(19) United States
(12) Patent Application Publication
(10) Pub. No.: US 2021/0104561 A1
(43) Pub. Date: Apr. 8, 2021

(54) SUB-PIXEL RESOLUTION FOR AN INDIVIDUAL OBSERVATION OF IONIZING RADIATION BY ELECTRODE GERRYMANDERING

(71) Applicant: Nikon Corporation, Tokyo (JP)

(72) Inventor: Heather L. Durko, Tucson, AZ (US)

(73) Assignee: Nikon Corporation, Tokyo (JP)

(21) Appl. No.: 17/063,466

(22) Filed: Oct. 5, 2020

Related U.S. Application Data
(60) Provisional application No. 62/911,667, filed on Oct. 7, 2019.

(51) Int. Cl. H01L 27/146; G01T 1/24

(52) U.S. Cl. CPC H01L 27/14607; H01L 27/14659; H01L 27/14661; G01T 1/24

(57) ABSTRACT

Techniques for sub-pixel resolution of an individual observation of ionizing radiation by electrode gerrymandering employ specialized pixel electrode geometries and a contracting-grid search to determine an energy deposition location and an estimate of the total deposited energy. Shaped pixel electrodes in a two-dimensional array of pixel electrodes enable redistribution of induced electrical signals to more than one pixel electrode by extending the pixel electrode's reach beyond that of a conventional pixel electrode so that an area or a portion of the pixel electrode is farther from its center than half a distance between its center and the pixel electrode center of an adjacent neighbor pixel electrode.

### CROSS REFERENCE TO OTHER APPLICATIONS

This application claims priority to U.S. Provisional Patent Application No. 62/911,667 entitled SUB-PIXEL RESOLUTION FOR AN INDIVIDUAL OBSERVATION OF X-RAY ABSORPTION filed Oct. 7, 2019, which is incorporated herein by reference for all purposes.

### BACKGROUND OF THE INVENTION

Energy deposited in an energy-resolving pixel detector by ionizing radiation is detected as an electrical signal associated with a pixel electrode location. Typically, the detector includes a two-dimensional array of pixel electrodes, the pixel electrode dimensions being sized such that the signal induced by carrier clouds is predominantly induced in one pixel electrode. However, the spatial resolution of the location of incidence is then limited to the pixel electrode size of the pixel electrodes in the two-dimensional array. Techniques for improved spatial resolution of an individual observation of ionizing radiation, including sub-pixel resolution, to determine a deposited energy and an energy deposition location would be advantageous to address this limitation in existing detection systems.

### BRIEF DESCRIPTION OF THE DRAWINGS

Various embodiments of the invention are disclosed in the following detailed description and the accompanying drawings.

FIG. 1A depicts an embodiment of a detector according to disclosed techniques.

FIG. 1B depicts an embodiment of pixel electrode centers as disclosed herein.

FIG. 1C depicts an embodiment of pixel electrode centers as disclosed herein.

FIG. 1D depicts an embodiment of pixel electrode centers as disclosed herein.

FIG. 1E depicts an embodiment of pixel electrode centers as disclosed herein.

FIG. 1F depicts an embodiment of pixel electrode centers as disclosed herein.

FIG. 2 depicts an embodiment of pixel electrodes as disclosed herein.

FIG. 3 depicts an embodiment of pixel electrodes as disclosed herein.

FIG. 4 depicts an embodiment of pixel electrodes as disclosed herein.

FIG. 5 depicts an embodiment of pixel electrodes as disclosed herein.

FIG. 6 depicts an embodiment of pixel electrodes as disclosed herein.

FIG. 7 depicts an embodiment of pixel electrodes as disclosed herein.

FIG. 8 depicts an embodiment of pixel electrodes as disclosed herein.

FIG. 9 depicts an embodiment of pixel electrodes as disclosed herein.

FIG. 10 depicts an embodiment of pixel electrodes as disclosed herein.

FIG. 11 depicts an embodiment of pixel electrodes as disclosed herein.

FIG. 12 depicts an embodiment of pixel electrodes as disclosed herein.

FIG. 13 depicts an embodiment of pixel electrodes as disclosed herein.

FIG. 14 depicts an embodiment of pixel electrodes as disclosed herein.

FIG. 15 depicts an embodiment of pixel electrodes as disclosed herein.

FIG. 16 depicts an embodiment of pixel electrodes as disclosed herein.

FIG. 17 depicts an embodiment of pixel electrodes as disclosed herein.

FIG. 18 depicts an embodiment of pixel electrodes as disclosed herein.

FIG. 19 depicts an embodiment of pixel electrodes as disclosed herein.

FIG. 20 depicts an embodiment of pixel electrodes as disclosed herein.

FIG. 21 depicts an embodiment of pixel electrodes as disclosed herein.

FIG. 22 depicts an embodiment of pixel electrodes as disclosed herein.

FIG. 23 depicts an embodiment of pixel electrodes as disclosed herein.

FIG. 24 is a flow diagram of an exemplary method for sub-pixel resolution of an individual observation of ionizing radiation by electrode gerrymandering.

FIG. 25 is a flow diagram of an exemplary method for determining an energy deposition location and a deposited energy of an individual observation of ionizing radiation.

FIG. 26 is a flow diagram of an exemplary method using a contracting-grid search algorithm to output a final energy deposition location and a final estimated deposited energy.

FIG. 27 is a visual depiction of a two-dimensional subset of a three-dimensional grid of test locations as described herein.

FIG. 28 is a visual depiction of a next iteration two-dimensional subset of a three-dimensional grid of test locations as described herein.

FIG. 29 is a block diagram of a computer system used in some embodiments to perform sub-pixel resolution of an individual observation of ionizing radiation by electrode gerrymandering.

FIG. 30 is a block diagram of a system used in some embodiments for sub-pixel resolution of an individual observation of ionizing radiation by electrode gerrymandering.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Energy deposited in a hybrid pixel detector by ionizing radiation is detected as an electrical signal associated with a pixel electrode location. The disclosed techniques generally employ an energy-resolving, spectroscopic, or photon-processing detector or any other detector having an ability to report information related to energy and position. Typically, the detector includes a two-dimensional array of pixel electrodes, the pixel electrode dimensions being sized such that the signal induced by carrier clouds is predominantly induced in one pixel electrode. The spatial resolution of the location of the energy deposition is then limited to the pixel electrode size of the pixel electrodes in the two-dimensional array. To address this limitation in existing detection systems, techniques are disclosed herein for improved spatial resolution of an individual observation of ionizing radiation, including sub-pixel resolution, to determine an energy deposition location.

In order for an energy deposition (e.g., an absorbed photon, photon/detector interaction, or ionizing radiation/detector interaction) to generate an event that is suitable for sub-pixel position estimation, it must create a cloud of charges that, by the time the cloud reaches collection electrodes with center-to-center spacing of distance P, must extend across an area that exceeds a circle that can be specified by a minimum charge-sharing radius (MCSR), defined here as the radius of the smallest possible circle centered at the energy deposition location that is tangent to the boundaries of at least two other pixels. In this context, a pixel includes a conceptual spatial representation of the measurement assigned to a location within a two-dimensional array of measurements.

Energy depositions near linear centers of a pixel electrode create charge clouds that do not extend to three or more pixel electrodes. This is because the diameter of the charge cloud is small compared to the pixel electrode size, which cannot extend across multiple pixel electrodes from certain locations. Energy depositions (e.g., absorbed photons) that do not create signals that extend across at least three pixels are not suitable for sub-pixel position estimation, and must be discarded.

For many high-energy detection applications, charge-sharing effects are unwanted and many detectors are designed with relatively large pixel dimensions in order to reduce the likelihood that a charge cloud will extend across pixel boundaries. However, for photon-counting or photon-processing applications, energy depositions such as individual photon absorptions can be visualized. When these absorptions are detected at three or more pixel electrodes, post-processing of the data can yield estimates of sub-pixel absorption locations, while charge shared across two or more pixel electrodes can improve information about the energy deposited in the detector crystal. Embodiments of energy deposition in detector bulk include photoelectric absorption, Compton scatter, Rayleigh scatter, and particle impact.

To increase the charge-sharing characteristics of pixelated detectors, there are two conventional approaches. A first approach is to reduce the pixel electrode size thereby increasing the number of pixel electrodes that cover the same detector area. This requires an increase in the number and density of the readout electronics and increases the complexity of achieving uniform adhesion and electrical contact across the numerous conducting bumps used to bump-bond the readout electronics to the detector slab. Readout electronics includes circuitry that converts an electric signal induced at the pixel electrode to a pixel output value (e.g., one of a two-dimensional array of measurements provided by a detector comprising a two-dimensional array of pixel electrodes). Many ionizing radiation detectors are made of relatively exotic semiconductors for which it can be more difficult to develop repeatable processing protocols compared to silicon, so increasing the density of bump bond is not necessarily straightforward.

A second conventional approach is to increase the detector thickness. This increases the distance that the charge clouds must drift across before they induce signals at the electrodes. Since the drift velocity does not change as a function of detector thickness, it will take longer for the clouds to travel to the electrodes, allowing more time for the charge clouds to diffuse laterally outward as they drift. The probability of photons generating charge clouds that extend across three or more pixel boundaries increases as a function of increasing detector thickness. However, due to processing limitations of newer semiconductor materials, it is not always possible to manufacture thicker slabs of these materials at a reasonable cost.

As an alternative to these two conventional charge-sharing improvement approaches, techniques are disclosed that include changing the shape of the pixel electrodes themselves so that the pixel electrodes are interlaced or interdigitated with adjacent neighbor pixel electrodes, making them sensitive to charges over larger area compared to conventional or standard pixel configurations and reducing the size of the area a charge cloud must span before it generates signals at three or more pixel electrodes. In particular, the MCSR is reduced for points across a pixel electrode through novel pixel electrode geometries (e.g., shaped pixel electrodes) that permit the pixel electrodes to extend across typical square or hexagonal boundaries. By changing the pixel electrode shape of the pixel electrodes in a two-dimensional pixel electrode array to permit portions of adjacent neighbor pixel electrodes to extend closer to the pixel electrode center of a given pixel electrode (where simultaneous distances to two or more pixel electrodes are the largest), charge clouds can be sampled by a greater number of pixel electrodes than would be possible with a standard electrode arrangement in currently existing systems.

Accordingly, the problem of improving spatial resolution to provide sub-pixel resolution for a detected energy deposition is addressed through techniques that include using a specialized geometry for a pixel electrode and computer processing to determine a likely sub-pixel energy deposition location. The specialized electrode geometry (e.g., shaped pixel electrodes) permit electrical signals to be induced in more than one pixel electrode for a given energy deposition (e.g., an absorbed photon, photon/detector interaction, or ionizing radiation/detector interaction). Electrical signals from the more than one pixel electrode are used to determine an energy deposition location that is at a higher resolution or accuracy than the native pixel resolution, defined as the center-to-center spacing of each pixel electrode. In energy-sensitive photon-counting or photon-processing configurations, or any detector that permits individual interactions to be observed, it is possible to estimate the sub-pixel energy deposition location where the energy deposition occurred from the measured electrical signals when the deposited energy is sufficient to induce electrical signals in three or more pixel electrodes in the region. When charge clouds that are created by the energy deposition are small relative to the size of the pixel electrode, only charge clouds that are created near the boundary of the pixels will be suitable for sub-pixel position estimation.

Techniques are disclosed for sub-pixel resolution of an individual observation of ionizing radiation by electrode gerrymandering. Examples of ionizing radiation include high-energy photons (e.g., x rays, gamma rays) and charged particles (e.g., electrons, protons, ions). Electrode gerrymandering in this context includes redistributing induced electrical signals to more than one pixel electrode at least in part by using a specialized pixel electrode geometry (e.g., shaped pixel electrodes) to modify the spatial boundaries that define a pixel area. For example, a specialized pixel electrode geometry includes shaping the pixel electrode to extend its reach so that an area or a portion of the pixel electrode is farther from its center than half a distance between its center and the pixel electrode center of an adjacent neighbor pixel electrode.

In some embodiments, a device for sub-pixel resolution of an individual observation of ionizing radiation by electrode gerrymandering comprises a detector that includes a two-dimensional array of pixel electrodes, each pixel electrode having a pixel electrode center (e.g., the geometric center of the pixel electrode). A pixel electrode can be configured to have a specialized geometry. In some embodiments, a pixel electrode of the two-dimensional array of pixel electrodes has an extent that is farther from its pixel electrode center than half a distance between the pixel electrode center and an adjacent neighbor's pixel electrode center.

Pixel output values are somewhat proportional to the signal that is induced in the pixel electrode. In other words, pixel output values can comprise one of a range of values, as opposed to being a binary number reported from the detection of a presence or absence of a signal determined as a result of whether the detected signal exceeds some threshold value (indicating that a signal either was or was not induced in the electrode). The detector of the disclosed device must be capable of some degree of energy resolution. As an example, the detector can be an energy-resolving, spectroscopic, or photon-processing detector or any other detector having an ability to report information related to energy and position (e.g., a detector comprising a two-dimensional array of spectroscopic pixel electrodes).

In some embodiments, the specialized pixel electrode geometry redistributes induced electrical signals to more than one pixel electrode by extending an area of the pixel electrode toward an adjacent neighbor's pixel electrode center past the half way point between the pixel electrode centers. In some cases, the pixel electrodes are tiled across the detector such that the pixel electrode centers are positioned on a grid. In particular, the pixel electrode centers are positioned on vertices of shapes on a shaped grid. Exemplary grid configurations can include shapes not limited to but including a parallelogram (e.g., square, rectangle, etc.), triangle, or a hexagon. For example, where a two-dimensional array of pixel electrodes is configured on a square grid, adjacent neighboring pixel electrode centers are at two distances—a closer distance and a farther distance (for diagonal adjacent neighbor pixel electrodes)—and the extension of the area of the pixel electrode away from its pixel electrode center is past the half way distance to the farthest distance between the pixel electrode centers.

In some embodiments, a method for sub-pixel resolution of an individual observation of ionizing radiation by electrode gerrymandering comprises detecting an electrical signal with a detector. The detector includes a two-dimensional array of pixel electrodes, each pixel electrode having a pixel electrode center. A pixel electrode of the two-dimensional array of pixel electrodes has an extent reaching an area farther from its pixel electrode center than half a distance between the pixel electrode center and an adjacent neighbor's pixel electrode center. The electrical signal being detected is generated in this area at some depth in the detector bulk away from the pixel electrodes. In some cases, the method also includes determining an energy deposition location and a deposited energy of an individual observation of ionizing radiation based at least in part on the detected electrical signal. In some cases, the estimated energy deposition location includes an estimated (x, y, z) energy deposition location.

In some embodiments, the extent of the pixel electrode is configured to be within a range of an electrical signal generated in a location that is farther from the pixel electrode center than half a distance between the pixel electrode center and an adjacent neighbor's pixel electrode center. In some embodiments, the detected electrical signal is induced at the pixel electrode and at least two adjacent neighbor pixel electrodes as charge carriers generated by ionizing radiation drift toward the pixel electrode and the at least two adjacent neighbor pixel electrodes. Examples of ionizing radiation include for example, high-energy photons (e.g., x rays, gamma rays) and charged particles (e.g., electrons, protons, ions).

Techniques as disclosed herein generally employ an energy-resolving, spectroscopic, or photon-processing detector or any other detector having an ability to report information related to energy and position. In some embodiments, the detector comprises a hybrid pixel detector comprising a bulk semiconductor crystal patterned with the two-dimensional array of pixel electrodes. The two-dimensional array of pixel electrodes is coupled to readout electronics. Ionizing radiation deposits energy in the bulk semiconductor crystal and generates charge carriers in an area of energy deposition. A bias voltage is applied across the bulk semiconductor crystal.

In some embodiments, the pixel electrodes are tiled across the detector such that the pixel electrode centers are positioned on vertices of a grid. In some cases, the vertices of the grid are configured to form a shape selected from the group consisting of: a parallelogram, a triangle, and a hexagon. The vertices of the grid may also be configured in other shapes or patterns, including compressed versions of the grid comprising compressed shapes such as parallelograms, triangles, and hexagons. Various grid configurations (e.g., square grids and equilateral triangular grids, some compressed in one dimension) are described herein.

In some embodiments, the extent of the pixel electrode comprises interdigitating extensions configured to interdigitate with an adjacent neighbor pixel electrode. In some cases, the extent of the pixel electrode comprises interdigitating extensions configured to interdigitate by branching and/or snaking with interdigitating extensions of an adjacent neighbor pixel electrode. The extensions of neighboring pixel electrodes can be branched to interdigitate, snaked to interdigitate, or tiled to interdigitate. The extensions from neighboring pixels can be placed close to each other so that an area excited by an energy deposition (e.g., the absorption of a photon or an x-ray) overlaps two, three, or more areas that extend from adjacent neighbor pixel electrodes. The pixel electrode can have extensions that repeat when rotated 90 degrees, 120 degrees, 180 degrees, or any other appropriate repeat rotation amount. Pixel electrodes can thus have two-fold symmetry, three-fold symmetry, four-fold symmetry, or any other symmetry.

Interdigitating extensions are configured to enable the extent of the pixel electrode to reach an area of an adjacent neighbor pixel electrode, the area being farther from the pixel electrode center than half a distance between the pixel electrode center and the adjacent neighbor's pixel electrode center. In some cases, interdigitating extensions are configured to enable the pixel electrode to sense an electrical signal generated in an area of an adjacent neighbor pixel electrode, the area being farther from the pixel electrode center than half a distance between the pixel electrode center and the adjacent neighbor's pixel electrode center.

Additional techniques are also disclosed to improve spatial resolution using a pixelated detector, where the resolution capabilities of existing systems are currently limited by pixel size. In particular, maximum-likelihood position estimation methods are applied, including a contracting-grid search algorithm, to determine an energy deposition location and a deposited energy of an individual observation of ionizing radiation.

In some embodiments, a method for determining an energy deposition location and a deposited energy of an individual observation of ionizing radiation based at least in part on a detected electrical signal comprises: receiving measured values for a pixel array corresponding to a signal being generated in a region of energy deposition; estimating a deposited energy in the region of energy deposition and an energy deposition location based at least in part on the measured values; and using the estimated deposited energy and the estimated energy deposition location as initial conditions, performing a maximum-likelihood position estimation method to output a final energy deposition location and a final estimated deposited energy. In some cases, performing a maximum-likelihood position estimation method comprises applying a contracting-grid search algorithm and a forward model to predict values for subsequent iterations of the contracting-grid search algorithm to output a final energy deposition location and a final estimated deposited energy upon convergence of the algorithm. In some cases, the estimated energy deposition location includes an estimated (x, y, z) energy deposition location and a sub-pixel resolution is achieved in determining the final energy deposition location. In some cases, a finer energy resolution is achieved in determining the final estimated deposited energy.

In some embodiments, a system for determining an energy deposition location of an individual observation of ionizing radiation comprises a processor and a memory coupled with the processor. The memory is configured to provide the processor with instructions that when executed cause the processor to: receive measured values for a pixel array corresponding to a signal being generated in a region of energy deposition; estimate a deposited energy in the region of energy deposition and an energy deposition location based at least in part on the measured values; and using the estimated deposited energy and the estimated energy deposition location as initial conditions, perform a maximum-likelihood position estimation method to output a final energy deposition location and a final estimated deposited energy. Performing a maximum-likelihood position estimation method can include applying a contracting-grid search algorithm and a forward model to predict values for subsequent iterations of the contracting-grid search algorithm to output a final energy deposition location and a final estimated deposited energy upon convergence of the algorithm. In some cases, the estimated energy deposition location includes an estimated (x, y, z) energy deposition location and a sub-pixel resolution is achieved in determining the final energy deposition location. In some cases, a finer energy resolution is achieved in determining the final estimated deposited energy.

In some embodiments, applying a contracting-grid search algorithm and a forward model to predict values for subsequent iterations of the contracting-grid search algorithm to output a final energy deposition location and a final estimated deposited energy upon convergence of the algorithm comprises: (a) defining a three-dimensional grid of test locations comprising a grid spacing and a center, the center being set at the estimated energy deposition location; (b) calculating, for each of the test locations, predicted values using the forward model; (c) computing, for each of the test locations, a merit function based on the predicted values and the measured values; (d) selecting one of the test locations as a best match location based on the computed merit functions; (e) if the best match location satisfies a convergence criteria, outputting the best match location as the final energy deposition location and the sum of the predicted values of the best match location as the final estimated deposited energy; and (f) if the best match location does not satisfy the convergence criteria, performing a next iteration of the contracting-grid search algorithm by contracting the grid spacing and setting the best match location as the estimated energy deposition location and then repeating steps (a) through (f) using the contracted grid spacing and the best match location as the grid center to provide test locations until one of the test locations selected as the best match location satisfies the convergence criteria.

In some embodiments, the system for determining an energy deposition location further comprises a detector comprising a two-dimensional array of pixel electrodes, each pixel electrode having a pixel electrode center, wherein a pixel electrode of the two-dimensional array of pixel electrodes has an extent that is farther from its pixel electrode center than half a distance between the pixel electrode center and an adjacent neighbor's pixel electrode center, wherein the detector is configured to provide the measured values.

In some embodiments, the memory is further configured to provide the processor with instructions which when executed cause the processor to receive measured data comprising a pixel array, each pixel in the pixel array having a measured pixel output value and to select a subset of pixels in the pixel array based on measured pixel output values that indicate a signal being generated in a region of energy deposition, the signal having been induced in pixel electrodes corresponding to the selected subset of pixels.

In some embodiments, a computer program product for determining an energy deposition location and deposited energy is disclosed, the computer program product being embodied in a tangible computer readable storage medium and comprising computer instructions for: receiving measured values for a pixel array corresponding to a signal being generated in a region of energy deposition; estimating a deposited energy in the region of energy deposition and an energy deposition location based at least in part on the measured values; and using the estimated deposited energy and the estimated energy deposition location as initial conditions, performing a maximum-likelihood position estimation method to output a final energy deposition location and a final estimated deposited energy. In some embodiments, performing a maximum-likelihood position estimation method comprises applying a contracting-grid search algorithm and a forward model to predict values for subsequent iterations of the contracting-grid search algorithm to output a final energy deposition location and a final estimated deposited energy upon convergence of the algorithm. In some cases, the estimated energy deposition location includes an estimated (x, y, z) energy deposition location and a sub-pixel resolution is achieved in determining the final energy deposition location. In some cases, a finer energy resolution is achieved in determining the final estimated deposited energy.

The computer program product can further comprise computer instructions for applying the contracting-grid search algorithm and the forward model to predict values for subsequent iterations of the contracting-grid search algorithm to output a final energy deposition location and a final estimated deposited energy upon convergence of the algorithm, including computer instructions for: (a) defining a three-dimensional grid of test locations comprising a grid spacing and a center, the center being set at the estimated energy deposition location; (b) calculating, for each of the test locations, predicted values using the forward model; (c) computing, for each of the test locations, a merit function based on the predicted values and the measured values; (d) selecting one of the test locations as a best match location based on the computed merit functions; (e) if the best match location satisfies a convergence criteria, outputting the best match location as the final energy deposition location and the sum of the predicted values of the best match location as the final estimated deposited energy; (f) if the best match location does not satisfy the convergence criteria, performing a next iteration of the contracting-grid search algorithm by contracting the grid spacing and setting the best match location as the estimated energy deposition location and then repeating steps (a) through (f) using the contracted grid spacing and the best match location as the grid center to provide test locations until one of the test locations selected as the best match location satisfies the convergence criteria. In some cases, the estimated energy deposition location includes an estimated (x, y, z) energy deposition location.

The computer program product can further comprise computer instructions for receiving measured data comprising a pixel array, each pixel in the pixel array having a measured pixel output value and selecting a subset of pixels in the pixel array based on measured pixel output values that indicate a signal being generated in a region of energy deposition, the signal having been induced in pixel electrodes corresponding to the selected subset of pixels.

In some cases, the measured values are received from a detector comprising a two-dimensional array of pixel electrodes, each pixel electrode having a pixel electrode center, wherein a pixel electrode of the two-dimensional array of pixel electrodes has an extent that is farther from its pixel electrode center than half a distance between the pixel electrode center and an adjacent neighbor's pixel electrode center. In such cases, the measured values comprise the measured pixel output values of the selected subset of pixels. The deposited energy in the region of energy deposition is estimated based at least in part on the measured pixel output values for the selected subset of pixels. The energy deposition location is estimated based at least in part on the measured pixel output values for the selected subset of pixels and a center-to-center spacing between the pixel electrodes corresponding to the selected subset of pixels. The predicted values comprise predicted pixel output values for the selected subset of pixels.

A contracting-grid search method using a contracting-grid search algorithm is but one way to perform a maximum-likelihood position estimation. Other ways to perform maximum-likelihood position estimation may be employed to determine an energy deposition location of an individual observation of ionizing radiation without limiting the scope of techniques as described herein. A discussion of the contracting-grid search algorithm and comparison to several alternative search methods can be found in Hesterman J Y, Caucci L, Kupinski M A, Barrett H H, Furenlid L R, Maximum-Likelihood Estimation With a Contracting-Grid Search Algorithm, IEEE Trans on Nucl Sci, 2010 Jun. 1; 57(3): 1077-1084, which is incorporated herein by reference for all purposes. In particular, alternative methods for performing maximum-likelihood position estimation include exhaustive search, subset search, nested search, directed search, and lookup tables. One advantage of applying a contracting-grid search algorithm to determine an energy deposition location is the ability to implement this algorithm in hardware.

In some embodiments, techniques for sub-pixel resolution of an individual observation of ionizing radiation by electrode gerrymandering include a device comprising a detector that includes a two-dimensional array of pixel electrodes. A specialized pixel electrode geometry (e.g., shaped pixel electrodes) enables redistributing induced electrical signals to more than one pixel electrode. A specialized pixel electrode geometry includes shaping the pixel electrode to modify the spatial boundaries that define a pixel area to extend its reach so that an area or a portion of the pixel electrode is farther from its center than half a distance between its center and the pixel electrode center of an adjacent neighbor pixel electrode.

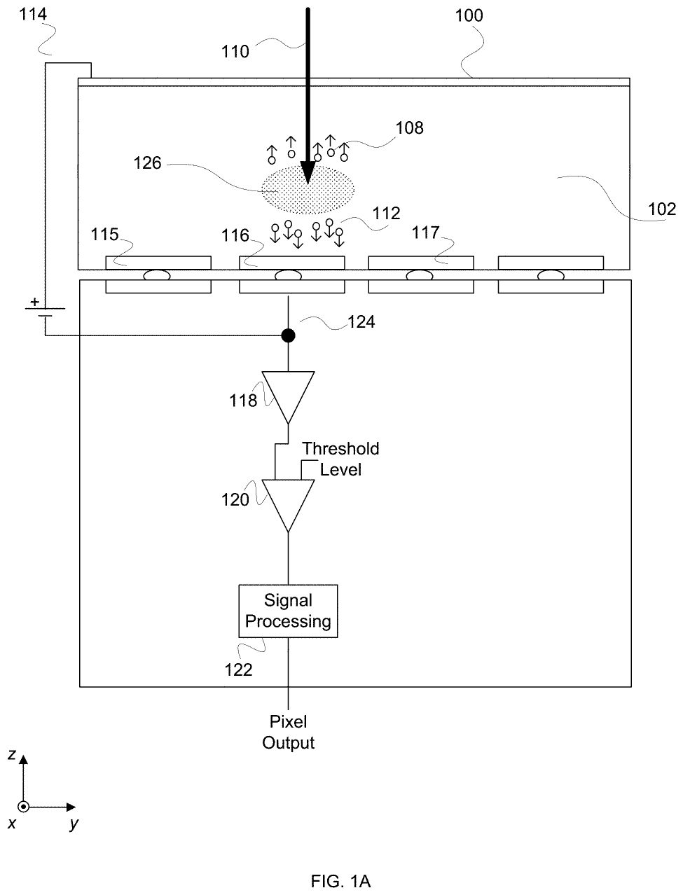

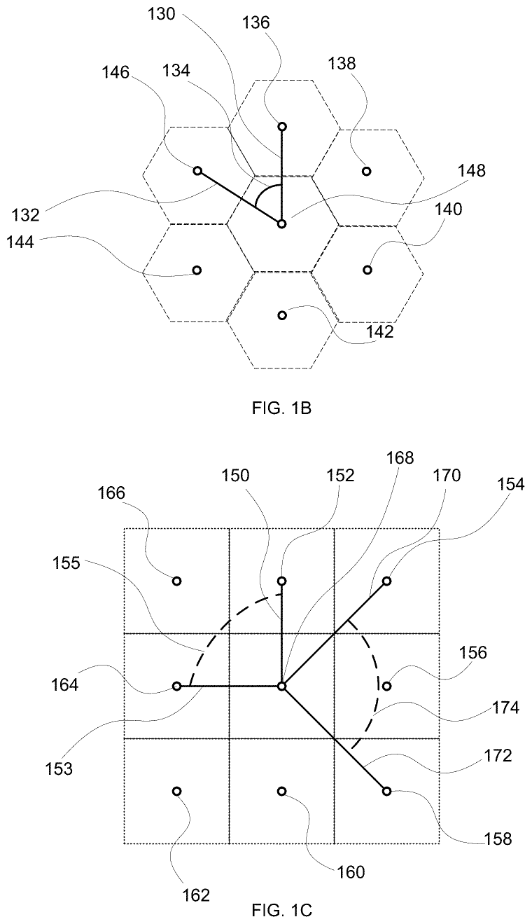

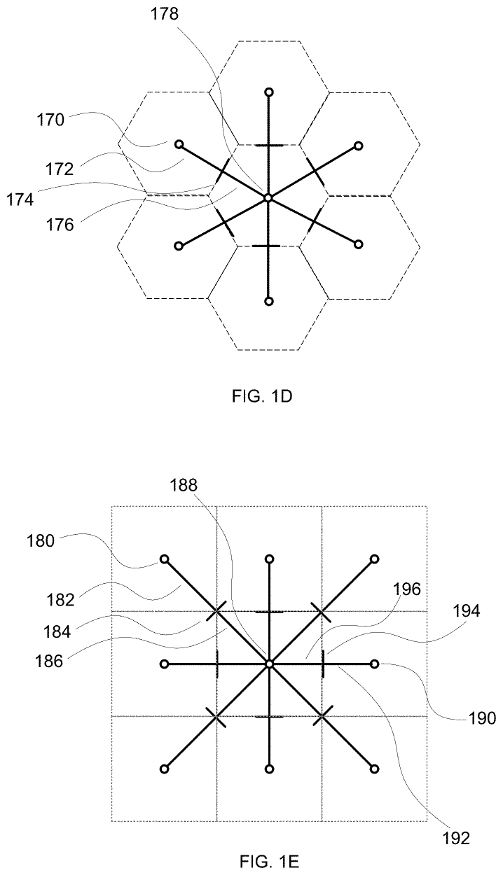

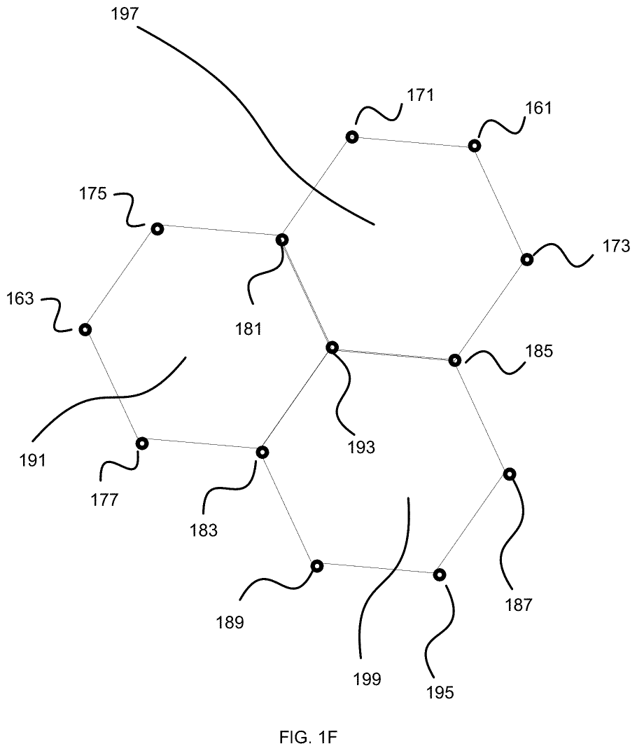

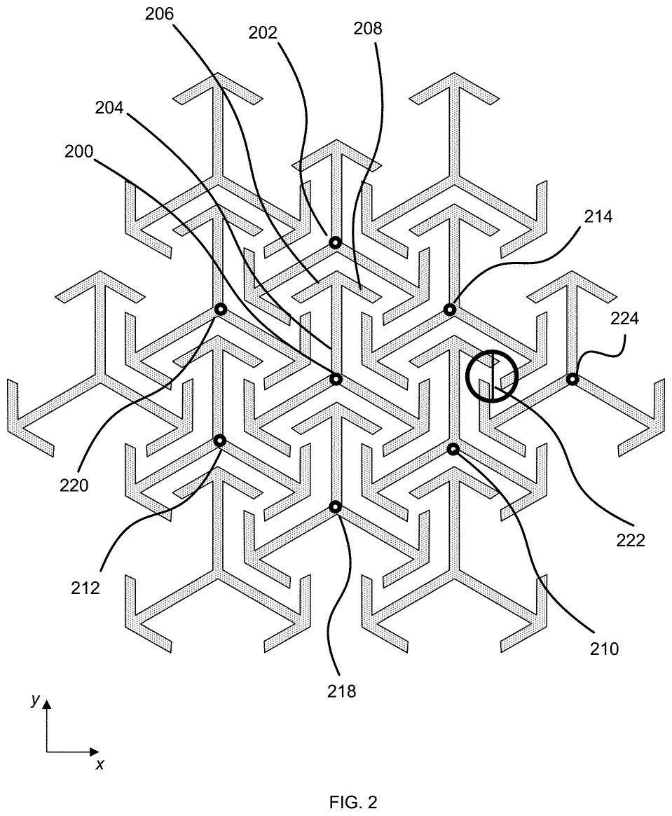

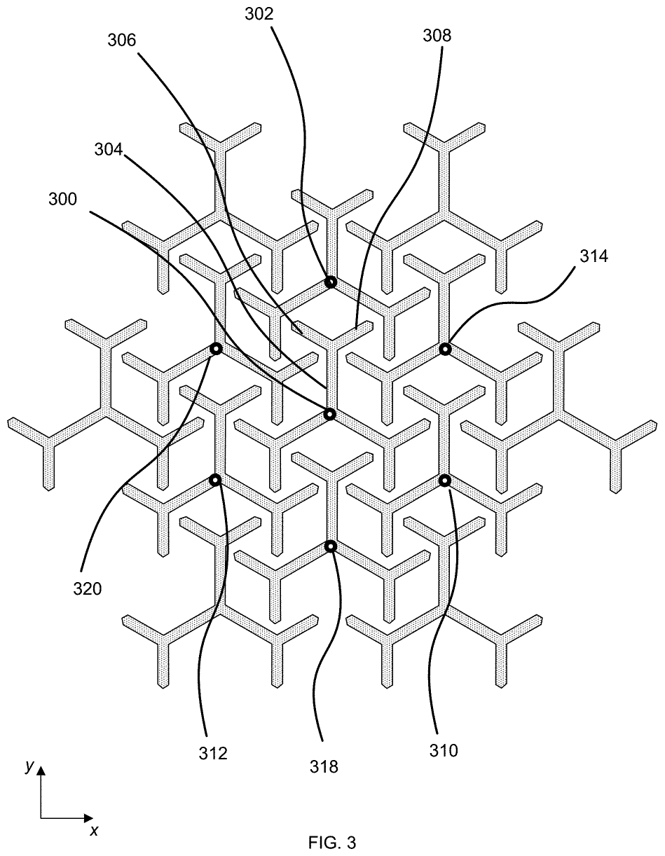

FIG. 1A is a diagram illustrating an embodiment of a pixel electrode. The pixel electrode of FIG. 1A is one of plurality of pixel electrodes forming the two-dimensional array of pixel electrodes in a detector as disclosed herein.

The disclosed techniques generally employ an energy-resolving, spectroscopic, or photon-processing detector or any other detector having an ability to report information related to energy and position. In some embodiments, the detector includes a hybrid pixel detector comprising a bulk semiconductor crystal patterned with the two-dimensional array of pixel electrodes. As described below with respect to FIG. 1A, ionizing radiation deposits energy in the bulk semiconductor crystal and generates charge carriers in an area of energy deposition. A bias voltage is applied across the bulk semiconductor crystal.

In the example of FIG. 1A, incident ionizing radiation 110 (e.g., high-energy photons such as x rays, and gamma rays and charged particles such as electrons, protons, and ions) with energy E deposits energy E_dep in material 102 (e.g., bulk semiconductor crystal) at location 126 to generate charge cloud 112 and charge cloud 108 that move toward electrode 100 and pixel electrode 116, respectively. Electrode 100 and pixel electrode 116 are held at different electrical potentials using circuit 114. In some embodiments, the bias is in the opposite direction for circuit 114. The charge cloud 112 drifts toward the pixel electrode 116 and, in doing so, induces an electrical signal (e.g., induced signal g(E_dep) 124) at pixel electrode 116 that is related to the deposited energy E_dep. In some embodiments, the charge cloud 108 also contributes to the induced signal 124 as it drifts away from the pixel electrode 116.

In some embodiments, the two-dimensional array of pixel electrodes is coupled to readout electronics. The readout electronics enable the system to provide a pixel output, for example, measured pixel output values that indicate a signal being generated in a region of energy deposition. In the example shown, the induced signal 124 is amplified by amplifier 118 and thresholded using comparator 120 with respect to a threshold level. Pulse processing performed by signal processing 122 converts the thresholded signal into a digital output that is proportional to the original signal that was induced. In some cases, there may also be DC offsets or other undesirable components of the signal. In some embodiments, the conversion from amplifier 118 is integrated instead of thresholded to determine the pixel output signal. In various embodiments, absorption material 102 comprises CdTe, Si, or any other appropriate material. FIG. 1A shows the readout electronics for a single pixel electrode 116 in the two-dimensional array of pixel electrodes. A similar electronic configuration exists for the other pixel electrodes in the two-dimensional array (e.g., adjacent neighbor pixel electrodes 115 and 117).

In various embodiments, because the ionizing radiation needs to be resolved individually, the detector comprises an energy-resolving photon-counting detector, or a photon-processing detector, or an integrating detector operated at a fast frame rate such that only one energy deposition occurs in a given region per frame, or any other appropriate detector. Embodiments of energy deposition in detector bulk include photoelectric absorption, Compton scatter, Rayleigh scatter, and particle impact.

As described with respect to FIG. 1A, an electrical signal (e.g., signal 124) is induced at the pixel electrode (e.g., pixel electrode 116). Although not shown, in some cases, the electrical signal is induced at the pixel electrode and at least two adjacent neighbor pixel electrodes (e.g., pixel electrodes 115 and 117) as the charge carriers generated by the ionizing radiation drift toward the pixel electrode and the at least two adjacent neighbor pixel electrodes.

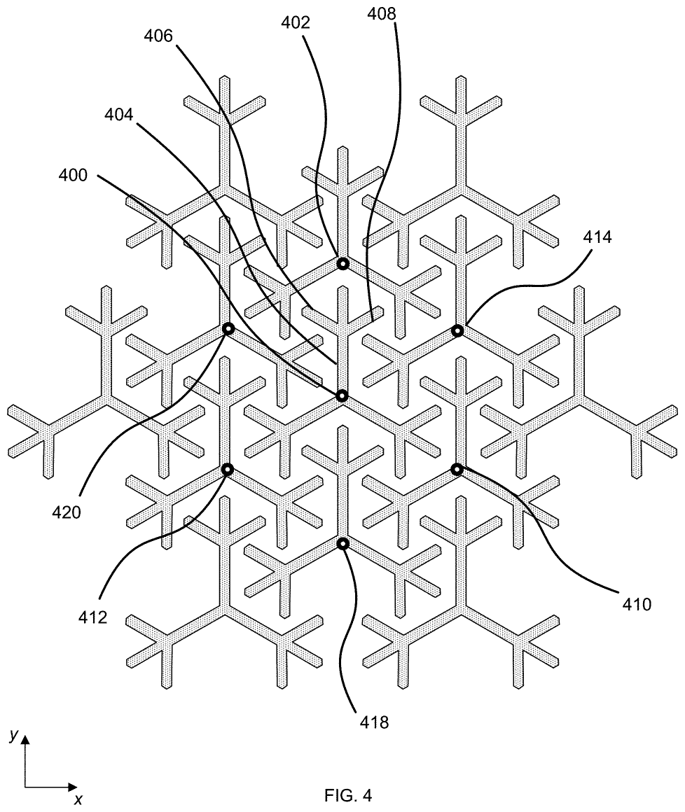

As described in more detail below with respect to FIGS. 1B-1F, each pixel electrode (e.g., pixel electrode 116 of FIG. 1A) in the two-dimensional array of pixel electrodes has a pixel electrode center. Additionally, as described with respect to FIGS. 2-23, a pixel electrode of the two-dimensional array of pixel electrodes is configured to have an extent that is farther from its pixel electrode center than half a distance between the pixel electrode center and an adjacent neighbor's pixel electrode center. The extent of the pixel electrode is configured to be within a range of an electrical signal generated in a location that is farther from the pixel electrode center than half a distance between the pixel electrode center and an adjacent neighbor's pixel electrode center. This configuration enables a pixel electrode according to the disclosed techniques to sense an electrical signal generated in the area of an adjacent neighbor pixel electrode that is beyond the reach of a conventional pixel electrode not having the same extent. According to some embodiments, a specialized pixel electrode geometry enables redistributing induced electrical signals to more than one pixel electrode. In these examples, a specialized pixel electrode geometry includes shaping the pixel electrode to extend its reach so that an area or a portion of the pixel electrode is farther from its center than half a distance between its center and the pixel electrode center of an adjacent neighbor pixel electrode.

FIG. 1B is a diagram illustrating an embodiment of pixel electrode centers. The pixel electrode centers comprise centers associated with pixel electrodes. The pixel electrodes are tiled across the detector such that the pixel electrode centers are positioned on vertices of a grid. In some cases, the vertices of the grid are configured to form a shape selected from the group consisting of: a parallelogram, a triangle, and a hexagon. In this case, the pixel electrode centers are positioned on vertices of equilateral triangles on an equilateral triangular grid. In particular, pixel electrode center 136, pixel electrode center 138, pixel electrode center 140, pixel electrode center 142, pixel electrode center 144, pixel electrode center 146, and pixel electrode center 148 are positioned on a triangular grid. In some embodiments, the grid is compressed along one dimension. In some embodiments, the extensions of an electrode from pixel electrode center 148 toward pixel electrode center 136 repeat as extensions of an electrode from pixel electrode center 148 toward pixel electrode center 144 (e.g., every 60 degrees—for example, electrode area extending along segment 130 rotated along arc 134 to be along segment 132).

FIG. 1C is a diagram illustrating an embodiment of pixel electrode centers. The pixel electrode centers comprise centers associated with pixel electrodes. The pixel electrodes are tiled across the detector such that the pixel electrode centers are positioned on vertices of a grid. Vertices of the grid are configured to form a shape selected from the group consisting of: a parallelogram, a triangle, and a hexagon. In this case, the pixel electrode centers are positioned on vertices of squares on a square grid. In particular, pixel electrode center 152, pixel electrode center 154, pixel electrode center 156, pixel electrode center 158, pixel electrode center 160, pixel electrode center 162, pixel electrode center 164, pixel electrode center 166, and pixel electrode center 168 are positioned on a square grid. In some embodiments, the grid is compressed along one dimension. In some embodiments, the extensions of an electrode from pixel electrode center 168 toward pixel electrode center 152 repeat as extensions of an electrode from pixel electrode center 168 toward pixel electrode center 164 (e.g., every 90 degrees—for example, electrode area extending along segment 150 rotated along arc 155 to be along segment 153). In some embodiments, the extensions of an electrode from pixel electrode center 168 toward pixel electrode center 154 repeat as extensions of an electrode from pixel electrode center 168 toward pixel electrode center 158 (e.g., every 90 degrees—for example, electrode area extending along segment 170 rotated along arc 174 to be along segment 158).

FIG. 1D is a diagram illustrating an embodiment of pixel electrode centers. The pixel electrode centers comprise centers associated with pixel electrodes. The pixel electrodes are tiled across the detector such that the pixel electrode centers are positioned on vertices of a grid. In some cases, the vertices of the grid are configured to form a shape selected from the group consisting of: a parallelogram, a triangle, and a hexagon. In this example, the pixel electrode centers are positioned on vertices of equilateral triangles on an equilateral triangular grid. In particular, pixel electrode centers positioned on a triangular grid include pixel electrode center 178 and pixel electrode center 170. Pixel electrode center 178 and pixel electrode center 170 are separated by distance 176 and distance 172 with half-way point 174.

FIG. 1E is a diagram illustrating an embodiment of pixel electrode centers. The pixel electrode centers comprise centers associated with pixel electrodes. The pixel electrodes are tiled across the detector such that the pixel electrode centers are positioned on vertices of a grid. In some cases, the vertices of the grid are configured to form a shape selected from the group consisting of: a parallelogram, a triangle, and a hexagon. In this example, the pixel electrode centers are positioned on vertices of squares on the square grid. In particular, pixel electrode centers in a square grid include pixel electrode center 188, pixel electrode center 180, and pixel electrode center 190. Pixel electrode center 188 and pixel electrode center 180 are farthest adjacent neighbors and are separated by distance 186 and distance 182 with half-way point 184. Pixel electrode center 188 and pixel electrode center 190 are nearest adjacent neighbors and are separated by distance 196 and distance 192 with half-way point 194.

FIG. 1F is a diagram illustrating an embodiment of pixel electrode centers. The pixel electrode centers comprise centers associated with pixel electrodes. The pixel electrodes are tiled across the detector such that the pixel electrode centers are positioned on vertices of a grid. Vertices of the grid are configured to form a shape selected from the group consisting of: a parallelogram, a triangle, and a hexagon. In this example, the pixel electrode centers are positioned on vertices of hexagons on the hexagonal grid. In particular, pixel electrode centers in a hexagonal grid include pixel electrode centers at the vertices of hexagon 197, hexagon 191, and hexagon 199. Pixel electrode center 193 has 3 nearest adjacent neighbors including pixel electrode center 181, pixel electrode center 183, and pixel electrode center 185. Pixel electrode center 193 has 6 next nearest adjacent neighbors (e.g., pixel electrode center 187 and pixel electrode center 189; pixel electrode center 171 and pixel electrode center 173; and pixel electrode center 175 and pixel electrode center 177). Pixel electrode center 193 has 3 farthest adjacent neighbors at the opposite vertex of the hexagon (e.g., pixel electrode center 195, pixel electrode center 161, and pixel electrode center 163).

FIGS. 2-23 illustrate embodiments of various configurations of pixel electrodes, and in particular, various examples of a specialized pixel electrode geometry (e.g., shaped pixel electrodes) that enable a redistribution of induced electrical signals to more than one pixel electrode. Different ways of shaping the pixel electrode to extend its reach so that an area or a portion of the pixel electrode is farther from its center than half a distance between its center and the pixel electrode center of an adjacent neighbor pixel electrode are shown.

The extent of the pixel electrodes shown in FIGS. 2-23 comprise interdigitating extensions configured to interdigitate with an adjacent neighbor pixel electrode. In some cases, the interdigitating extensions interdigitate by branching and/or snaking with interdigitating extensions of an adjacent neighbor pixel electrode. In some cases, the interdigitating extensions are configured to repeat when rotated a certain number of degrees (e.g., 90 degrees, 120 degrees, or 180 degrees). Interdigitating extensions are configured to enable the extent of the pixel electrode to reach an area of an adjacent neighbor pixel electrode, and/or to sense an electrical signal generated in an area of an adjacent neighbor pixel electrode, the area being farther from the pixel electrode center than half a distance between the pixel electrode center and the adjacent neighbor's pixel electrode center.

FIG. 2 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. In this particular case, shaped pixel electrodes are positioned with their centers on vertices of equilateral triangles on an equilateral triangular grid as in FIGS. 1B and 1D.

As shown in FIG. 2, a shaped pixel electrode comprises interdigitating extensions configured to interdigitate with an adjacent neighbor pixel electrode. In the example shown, the extent of the shaped pixel electrode comprises interdigitating extensions configured to interdigitate by branching with interdigitating extensions of an adjacent neighbor pixel electrode. In this case, a shaped pixel electrode associated with pixel electrode center 200 has an electrode extension 204 toward pixel electrode center 202. The end of electrode extension 204 branches to the right (right branch 208) and to the left (left branch 206) 60 degrees from the body of electrode extension 204 to form an arrow-like shape. The shaped pixel electrode associated with pixel electrode center 200 has a repeat of electrode extension 204 every 120 degrees toward pixel electrode center 210 and pixel electrode center 212. The branches of the shaped pixel electrode associated with pixel electrode center 200 interdigitate with electrode extensions from shaped pixel electrodes associated with pixel electrode center 214, pixel electrode center 218, and pixel electrode center 220 as well as pixel electrode center 202, pixel electrode center 210, and pixel electrode center 212 respectively. The shaped pixel electrodes tile together.

In some embodiments, circle 222 depicts the xy lateral extent of a charge cloud created by an energy deposition. The electrode extensions enable the signal from the charge cloud to induce a signal in three shaped pixel electrodes associated with three pixel electrode center locations (e.g., pixel electrode center 214, pixel electrode center 210, and pixel electrode center 224). The spreading of the signal over a plurality of pixel electrodes occurs because more than one pixel electrode's extensions fall within a distance equivalent to the diameter of circle 222. The extent of the pixel electrode (e.g., via electrode extensions of a shaped pixel electrode) is configured to be within a range of an electrical signal generated in a location that is farther from the pixel electrode center than half a distance between the pixel electrode center and an adjacent neighbor's pixel electrode center. This expanded reach of the pixel electrode extent permits a shaped pixel electrode to be within the range of an electrical signal that is outside the conventional area within the scope of detection for a pixel electrode in current systems that lack the novel geometries for shaped pixel electrodes according to the disclosed techniques.

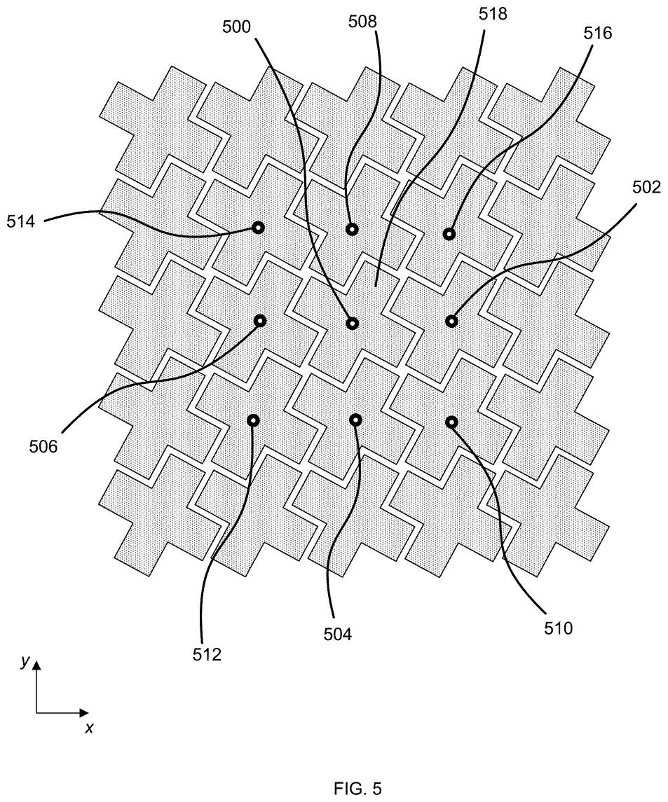

FIG. 3 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 3, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. In this case, a shaped pixel electrode associated with pixel electrode center 300 has an electrode extension 304 toward pixel electrode center 302. The end of electrode extension 304 branches to the right (right branch 308) and to the left (left branch 306) 120 degrees from the body of electrode extension 304 to form a “Y” shape. The shaped pixel electrode associated with pixel electrode center 300 has a repeat of electrode extension 304 every 120 degrees toward pixel electrode center 310 and pixel electrode center 312. The branches of the shaped pixel electrode associated with pixel electrode center 300 interdigitate with electrode extensions from shaped pixel electrodes associated with pixel electrode center 314, pixel electrode center 318, and pixel electrode center 320 as well as pixel electrode center 302, pixel electrode center 310, and pixel electrode center 312 respectively. The shaped pixel electrodes tile together.

FIG. 4 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 4, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 400 has an electrode extension 404 toward pixel electrode center 402. The end of electrode extension 404 branches to the right (right branch 408) and to the left (left branch 406) 120 degrees from the body of electrode extension 404 to form a fork shape (e.g., “Y” shape with a center spike). The shaped pixel electrode associated with pixel electrode center 400 has a repeat of electrode extension 404 every 120 degrees toward pixel electrode center 410 and pixel electrode center 412. The branches of the shaped pixel electrode associated with pixel electrode center 400 interdigitate with electrode extensions from shaped pixel electrodes associated with pixel electrode center 414, pixel electrode center 418, and pixel electrode center 420 as well as pixel electrode center 402, pixel electrode center 410, and pixel electrode center 412 respectively. The shaped pixel electrodes tile together.

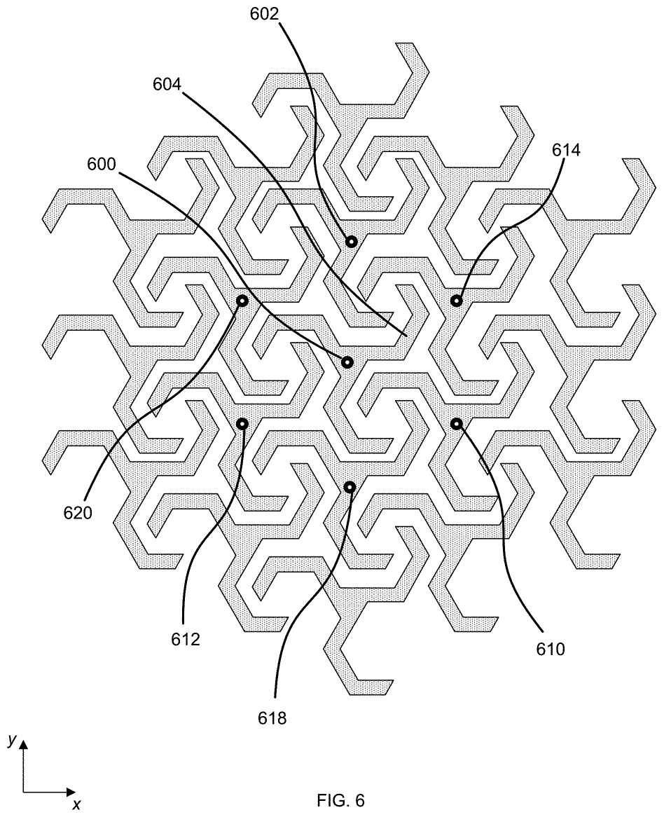

FIG. 5 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 5, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. In this case, a shaped pixel electrode associated with pixel electrode center 500 has an electrode extension 518 toward the shaped pixel electrode associated with pixel electrode center 508. The end of electrode extension 518 forms a tab shape extending toward the shaped pixel electrodes associated with pixel electrode center 508. The shaped pixel electrode associated with pixel electrode center 500 has a repeat of electrode extension 518 every 90 degrees toward the shaped pixel electrodes associated with pixel electrode center 502, pixel electrode center 504, and pixel electrode center 506. The branches of the shaped pixel electrode associated with pixel electrode center 500 interdigitate with electrode extensions from shaped pixel electrodes associated with pixel electrode center 502, pixel electrode center 504, pixel electrode center 506, and pixel electrode center 508 respectively. The shaped pixel electrodes tile together.

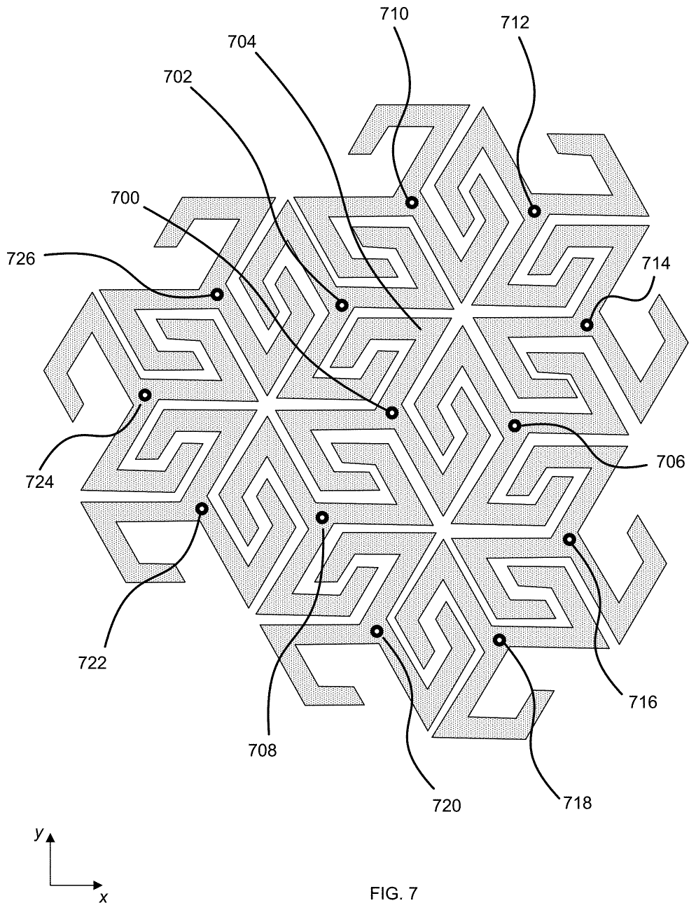

FIG. 6 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 6, a shaped pixel electrode comprises interdigitating extensions configured to interdigitate with an adjacent neighbor pixel electrode. The extent of the shaped pixel electrode comprises interdigitating extensions configured to interdigitate by branching and/or snaking with interdigitating extensions of an adjacent neighbor pixel electrode. A shaped pixel electrode associated with pixel electrode center 600 has an electrode extension 604 toward pixel electrode center 602. The end of electrode extension 604 forms a “C” shape extending toward pixel electrode center 614. The shaped pixel electrode associated with pixel electrode center 600 has a repeat of electrode extension 604 every 120 degrees toward pixel electrode center 620 and pixel electrode center 618. The branches of the shaped pixel electrode associated with pixel electrode center 600 snake to interdigitate with electrode extensions from shaped pixel electrodes associated with pixel electrode center 602, pixel electrode center 610, and pixel electrode center 612 as well as pixel electrode center 614, pixel electrode center 618, and pixel electrode center 620 respectively. The shaped pixel electrodes tile together.

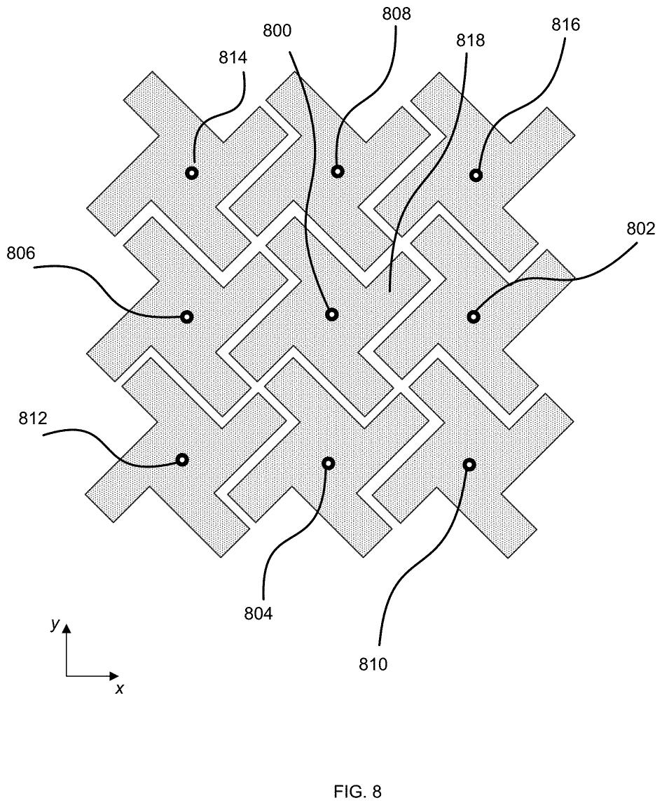

FIG. 7 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIG. 1F.

As shown in FIG. 7, a shaped pixel electrode comprises interdigitating extensions configured to interdigitate with an adjacent neighbor pixel electrode. The extent of the shaped pixel electrode comprises interdigitating extensions configured to interdigitate by branching and/or snaking with interdigitating extensions of an adjacent neighbor pixel electrode. In this case, a shaped pixel electrode associated with pixel electrode center 700 has an electrode extension 704 toward pixel electrode center 702. The end of electrode extension 704 forms a “C” shape extending toward pixel electrode center 702. The shaped pixel electrode associated with pixel electrode center 700 has a repeat of electrode extension 704 every 120 degrees toward pixel electrode center 708 and pixel electrode center 706. The branches of the shaped pixel electrode associated with pixel electrode center 700 snake to interdigitate with electrode extensions from shaped pixel electrodes associated with pixel electrode center 702, pixel electrode center 706, and pixel electrode center 708 respectively. Other adjacent neighbor pixel electrodes include shaped pixel electrodes associated with pixel electrode center 710, farthest adjacent pixel electrode center 712, pixel electrode center 714; pixel electrode center 716, farthest adjacent pixel electrode center 718, pixel electrode center 720; and pixel electrode center 722, farthest adjacent pixel electrode center 724, and pixel electrode center 726 respectively. The shaped pixel electrodes of FIG. 7 tile together. Note that electrode extension 704 extends farther than half way to the nearest adjacent pixel electrode centers, but not to the farthest adjacent pixel electrode centers.

FIG. 8 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 8, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. In this case, a shaped pixel electrode associated with pixel electrode center 800 has an electrode extension 818 toward the shaped pixel electrodes associated with pixel electrode center 802. The end of electrode extension 818 forms a tab shape extending toward the shaped pixel electrode associated with pixel electrode center 802. The shaped pixel electrode associated with pixel electrode center 800 has a repeat of electrode extension 818 every 90 degrees toward the shaped pixel electrodes associated with pixel electrode center 804, pixel electrode center 806, and pixel electrode center 810. The branches of the shaped pixel electrode associated with pixel electrode center 800 interdigitate with electrode extensions from shaped pixel electrodes associated with pixel electrode center 802, pixel electrode center 804, pixel electrode center 806, and pixel electrode center 808 respectively. The shaped pixel electrodes tile together.

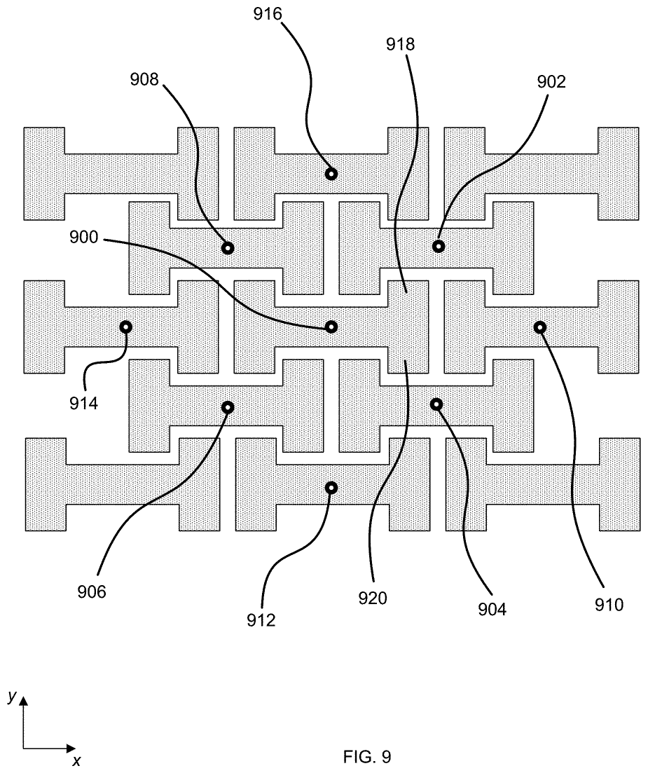

FIG. 9 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of parallelograms on a parallelogram grid; also note that a parallelogram can also be considered as a compression of a square in a direction defined by a line connecting two non-adjacent vertices of the parallelogram. Shaped pixel electrodes are positioned with their centers on vertices of a parallelogram on a parallelogram grid.

As shown in FIG. 9, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. In this case, a shaped pixel electrode associated with pixel electrode center 900 has an electrode extension 918 toward a shaped pixel electrode associated with pixel electrode center 910. The end of electrode extension forms a tab shape 918 extending on one end in a first direction toward pixel electrode center 902. The end of electrode extension forms a tab shape 920 extending on the other end in a second direction opposite the first direction toward pixel electrode center 904. The shaped pixel electrode associated with pixel electrode center 900 has a repeat of electrode extension 918 every 180 degrees toward the shaped pixel electrode associated with pixel electrode center 914. The branches of the shaped pixel electrode associated with pixel electrode center 900 interdigitate with electrode extensions from shaped pixel electrodes associated with pixel electrode center 902, pixel electrode center 904, pixel electrode center 906, and pixel electrode center 908 respectively. The branches of the shaped pixel electrode associated with pixel electrode center 900 abut the shaped pixel electrodes associated with pixel electrode centers 910 and pixel electrode center 914. The shaped pixel electrodes tile together.

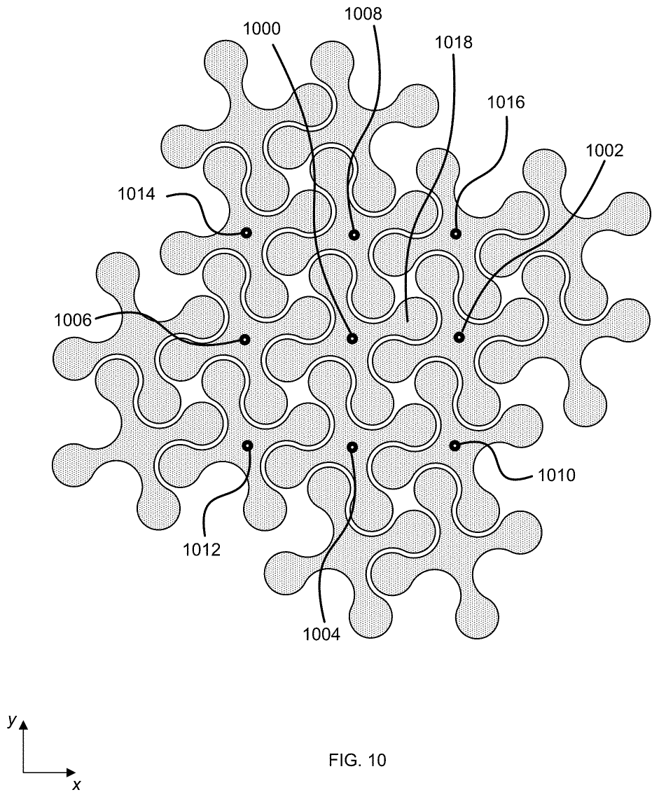

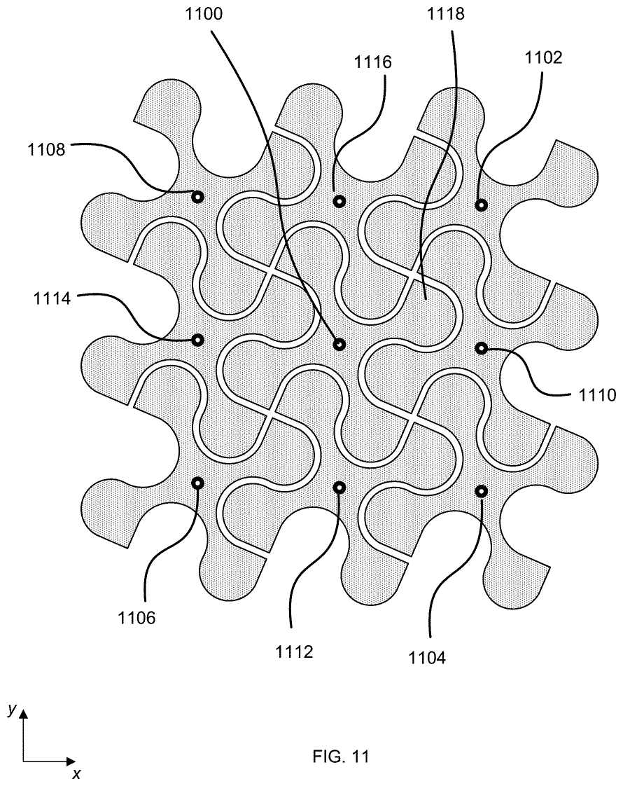

FIG. 10 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 10, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1000 has an electrode extension 1018 toward pixel electrode center 1002. The end of electrode extension 1018 forms a tab shape extending toward the shaped pixel electrode associated with pixel electrode center 1002. The shaped pixel electrode associated with pixel electrode center 1000 repeats electrode extension 1018 every 90 degrees toward pixel electrode center 1002, pixel electrode center 1004, pixel electrode center 1006, and pixel electrode center 1008. Branches of the shaped pixel electrode associated with pixel electrode center 1000 interdigitate with electrode extensions from shaped pixel electrodes associated with pixel electrode center 1002, pixel electrode center 1004, pixel electrode center 1006, and pixel electrode center 1008 respectively. The shaped pixel electrodes tile together.

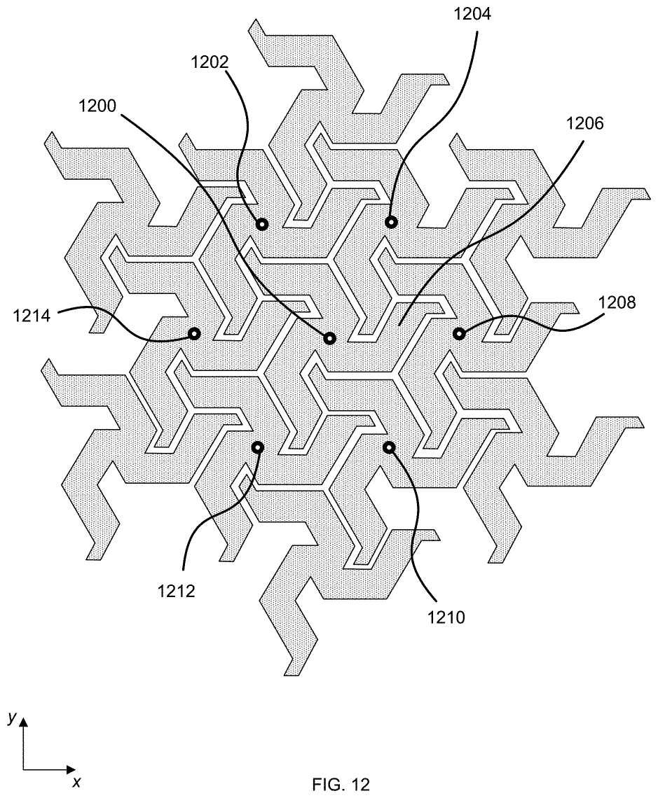

FIG. 11 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 11, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1100 has an electrode extension 1118 toward the shaped pixel electrode associated with pixel electrode center 1110. The end of electrode extension 1118 forms a tab shape extending toward the shaped pixel electrode associated with pixel electrode center 1110. The shaped pixel electrode associated with pixel electrode center 1100 repeats electrode extension 1118 every 90 degrees toward the shaped pixel electrode associated with pixel electrode center 1112, the shaped pixel electrode associated with pixel electrode center 1114, and the shaped pixel electrode associated with pixel electrode center 1116. Branches of the shaped pixel electrode associated with pixel electrode center 1100 interdigitate with electrode extensions from shaped pixel electrodes associated with pixel electrode center 1110, pixel electrode center 1112, pixel electrode center 1114, and pixel electrode center 1116 respectively. The shaped pixel electrodes tile together.

FIG. 12 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 12, a shaped pixel electrode comprises interdigitating extensions configured to interdigitate with an adjacent neighbor pixel electrode. The extent of the shaped pixel electrode comprises interdigitating extensions configured to interdigitate by branching and/or snaking with interdigitating extensions of an adjacent neighbor pixel electrode. A shaped pixel electrode associated with pixel electrode center 1200 has an electrode extension 1206 toward pixel electrode center 1208. The end of electrode extension 1206 forms a “C” shape with a little finger pointed away from the center of the “C” shape and almost reaching the neighboring pixel electrode center 1208. The shaped pixel electrode associated with pixel electrode center 1200 repeats electrode extension 1206 every 120 degrees toward pixel electrode center 1212 and pixel electrode center 1202. Branches of the shaped pixel electrode associated with pixel electrode center 1200 snake to interdigitate with electrode extensions from shaped pixel electrodes associated with pixel electrode center 1202, pixel electrode center 1208, and pixel electrode center 1212 as well as from shaped pixel electrodes associated with pixel electrode center 1204, pixel electrode center 1210, and pixel electrode center 1214 respectively. The shaped pixel electrodes tile together.

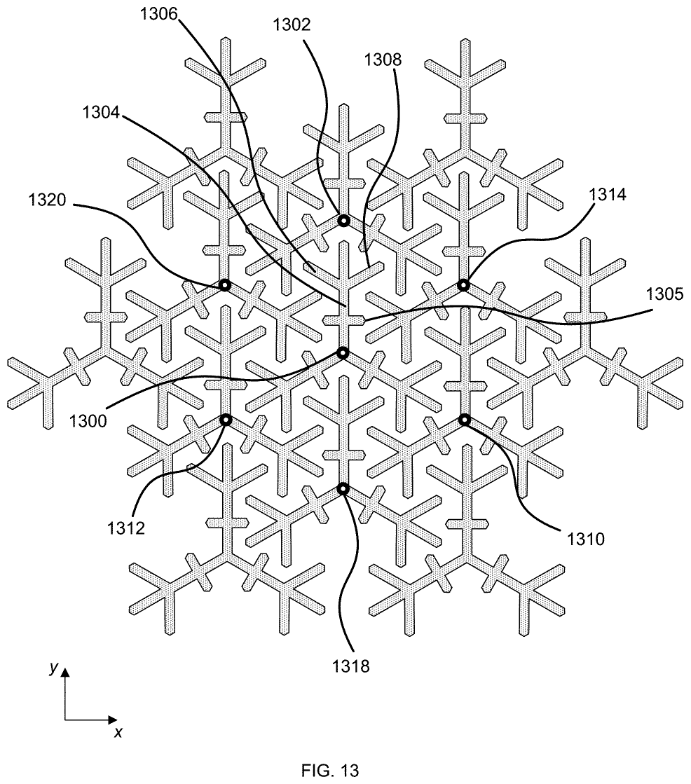

FIG. 13 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 13, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1300 has an electrode extension 1304 toward the shaped pixel electrode associated with pixel electrode center 1302. The end of electrode extension 1304 branches to the right (right branch 1308) and to the left (left branch 1306) 120 degrees from the body of electrode extension 1304 to form a fork shape (e.g., “Y” shape with a center spike). Electrode extension 1304 also includes a cross bar 1305 half way up the base of the “Y”. The shaped pixel electrode associated with pixel electrode center 1300 repeats electrode extension 1304 every 120 degrees toward pixel electrode center 1310 and pixel electrode center 1312. The branches of the shaped pixel electrode associated with pixel electrode center 1300 interdigitate with electrode extensions from shaped pixel electrodes associated with pixel electrode center 1302, pixel electrode center 1310, and pixel electrode center 1312 as well as from shaped pixel electrodes associated with pixel electrode center 1314, pixel electrode center 1318, and pixel electrode center 1320 respectively. The shaped pixel electrodes tile together.

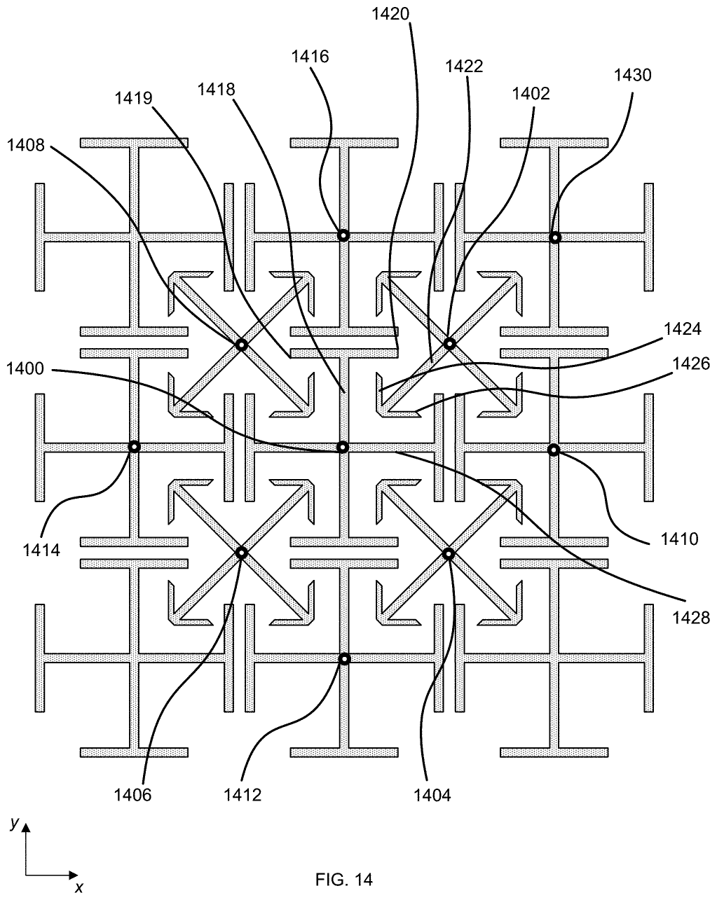

FIG. 14 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 14, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. In this case, there are two different pixel geometries that alternate: one with “T”-shaped ends (e.g., shaped pixel electrodes associated with pixel electrode center 1416, pixel electrode center 1414, pixel electrode center 1400, pixel electrode center 1410, and pixel electrode center 1412) and one with arrow-shaped ends (e.g., shaped pixel electrodes associated with pixel electrode center 1408, pixel electrode center 1402, pixel electrode center 1406, and pixel electrode center 1404). A shaped pixel electrode associated with pixel electrode center 1400 has an electrode extension 1418 toward the shaped pixel electrode associated with pixel electrode center 1416. The end of electrode extension 1418 forms a “T” shape extending toward pixel electrode center 1416, wherein one side 1419 of the top of the “T” extends toward pixel electrode center 1408, and the other side 1420 of the top of the “T” extends toward pixel electrode center 1402. The shaped pixel electrode associated with pixel electrode center 1400 has a repeat of electrode extension 1418 every 90 degrees toward the shaped pixel electrodes associated with pixel electrode center 1410, pixel electrode center 1412, and pixel electrode center 1414 respectively. The branches of the shaped pixel electrode associated with pixel electrode center 1400 interdigitate with electrode extensions from shaped pixel electrodes associated with pixel electrode center 1402, pixel electrode center 1404, pixel electrode center 1406, and pixel electrode center 1408 respectively. The alternating shapes have either “T” shapes or arrow shapes (e.g., the shaped pixel electrode associated with pixel electrode center 1402 with arrow shape extension 1422). A shaped pixel electrode associated with pixel electrode center 1402 has an electrode extension 1422 toward the shaped pixel electrode associated with pixel electrode center 1400. The end of electrode extension 1422 forms an arrow shape extending toward pixel electrode center 1400, wherein one side 1424 of the arrow extends in the same direction as electrode extension 1418, and the other side 1426 of the arrow extends in the same direction as electrode extension 1428. The shaped pixel electrode associated with pixel electrode center 1402 has a repeat of electrode extension 1422 every 90 degrees toward the shaped pixel electrodes associated with pixel electrode center 1416, pixel electrode center 1430, and pixel electrode center 1410 respectively. The shaped pixel electrodes tile together.

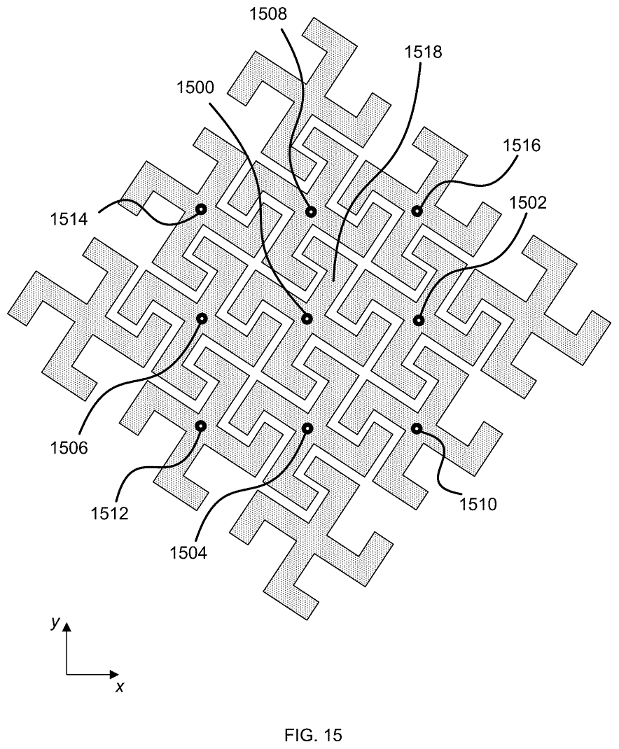

FIG. 15 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 15, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1500 has an electrode extension 1518 towards the shaped pixel electrode associated with pixel electrode center 1508. The end of electrode extension 1518 forms an “L” shape extending toward the shaped pixel electrode associated with pixel electrode center 1508. The shaped pixel electrode associated with pixel electrode center 1500 has a repeat of electrode extension 1518 every 90 degrees toward the shaped pixel electrodes associated with pixel electrode center 1502, pixel electrode center 1504, and pixel electrode center 1506 respectively. The branches of the shaped pixel electrode associated with pixel electrode center 1500 interdigitate with electrode extensions from shaped pixel electrodes associated with pixel electrode center 1508, pixel electrode center 1502, pixel electrode center 1504, and pixel electrode center 1506 respectively. The shaped pixel electrodes tile together.

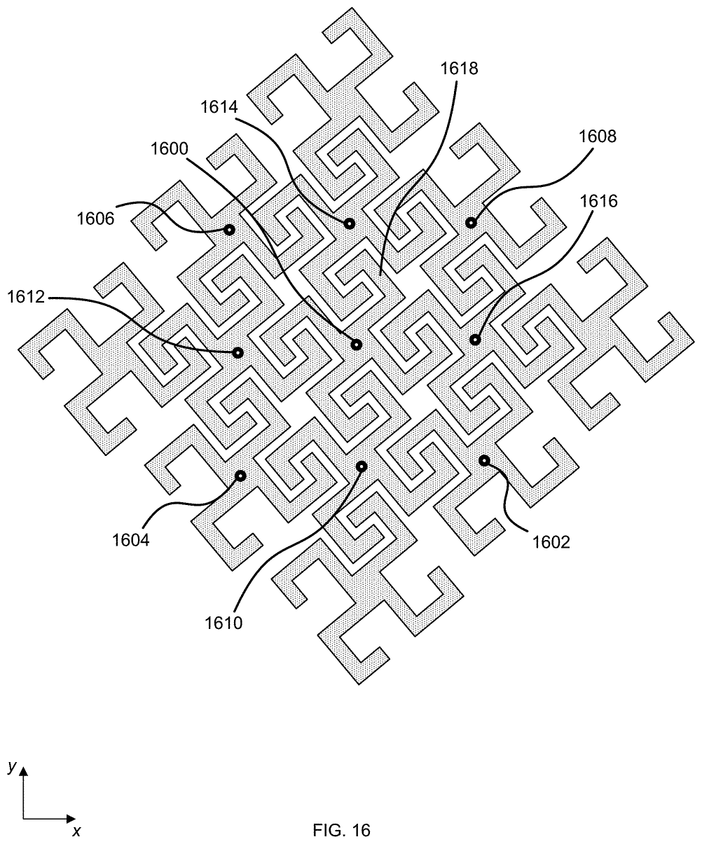

FIG. 16 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 16, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1600 has an electrode extension 1618 toward the shaped pixel electrode associated with pixel electrode center 1608. The end of electrode extension 1618 forms an “C” shape extending toward the shaped pixel electrode associated with pixel electrode center 1614. The shaped pixel electrode associated with pixel electrode center 1600 repeats electrode extension 1618 every 90 degrees toward the shaped pixel electrodes associated with pixel electrode center 1616, pixel electrode center 1610, and pixel electrode center 1612. Branches of the shaped pixel electrode associated with pixel electrode center 1600 interdigitate with electrode extensions from shaped pixel electrodes associated with pixel electrode center 1610, pixel electrode center 1612, pixel electrode center 1614, and pixel electrode center 1616 respectively. The shaped pixel electrodes tile together.

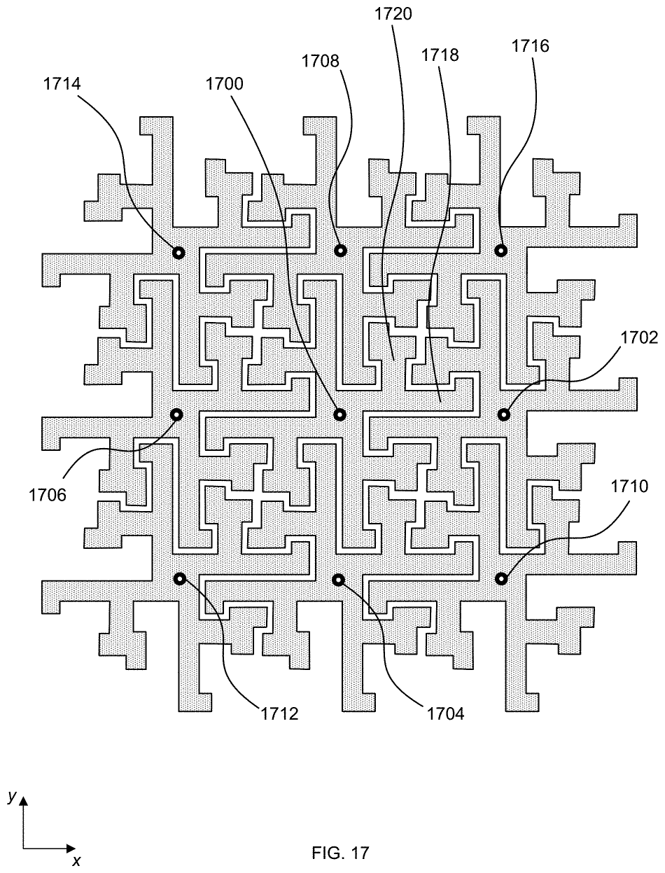

FIG. 17 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 17, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1700 has an electrode extension 1718 toward pixel electrode center 1702. The end of electrode extension 1718 forms an “L” shape extending toward pixel electrode center 1702. A second electrode extension 1720 extends from partway along electrode extension 1718 toward the shaped pixel electrode associated with pixel electrode center 1708. The shaped pixel electrode associated with pixel electrode center 1700 has a repeat of electrode extension 1718 every 90 degrees toward the shaped pixel electrodes associated with pixel electrode center 1704, pixel electrode center 1706, and pixel electrode center 1708. The branches of the shaped pixel electrode associated with pixel electrode center 1700 interdigitate with electrode extensions from shaped pixel electrodes associated with pixel electrode center 1702, pixel electrode center 1704 pixel electrode center 1706, and pixel electrode center 1708 respectively. The shaped pixel electrodes tile together.

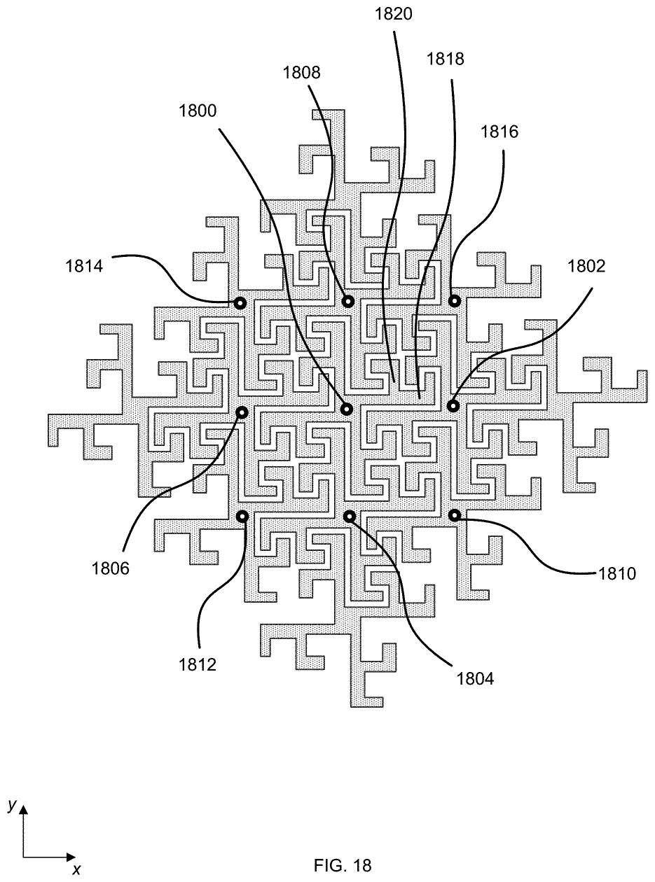

FIG. 18 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 18, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1800 has an electrode extension 1818 toward pixel electrode center 1802. The end of electrode extension 1818 forms an extended “L” shape extending toward pixel electrode center 1802. A second electrode extension 1820 extends from partway along electrode extension 1818 toward the shaped pixel electrode associated with pixel electrode center 1808. The shaped pixel electrode associated with pixel electrode center 1800 has a repeat of electrode extension 1818 every 90 degrees toward the shaped pixel electrodes associated with pixel electrode center 1804, pixel electrode center 1806, and pixel electrode center 1808. The branches of the shaped pixel electrode associated with pixel electrode center 1800 interdigitate with electrode extensions from shaped pixel electrodes associated with pixel electrode center 1802, pixel electrode center 1804 pixel electrode center 1806, and pixel electrode center 1808 respectively. The shaped pixel electrodes tile together.

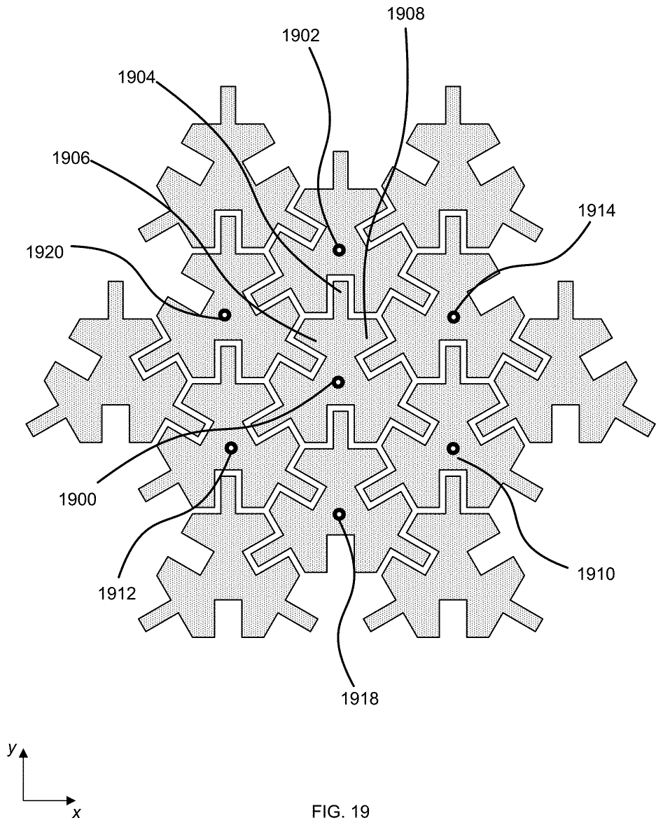

FIG. 19 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 19, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 1900 has an electrode extension 1904 toward pixel electrode center 1902. The sides of electrode extension 1904 branch to the right (right branch 1908) and to the left (left branch 1906) 120 degrees from the body of electrode extension 1904 to form a wing shape. The shaped pixel electrode associated with pixel electrode center 1900 has a repeat of electrode extension 1904 every 120 degrees toward pixel electrode center 1910 and pixel electrode center 1912. The branches of the shaped pixel electrode associated with pixel electrode center 1900 interdigitate with electrode extensions from shaped pixel electrodes associated with pixel electrode center 1902, pixel electrode center 1910, and pixel electrode center 1912 as well as pixel electrode center 1914, pixel electrode center 1918, and pixel electrode center 1920 respectively. The shaped pixel electrodes tile together.

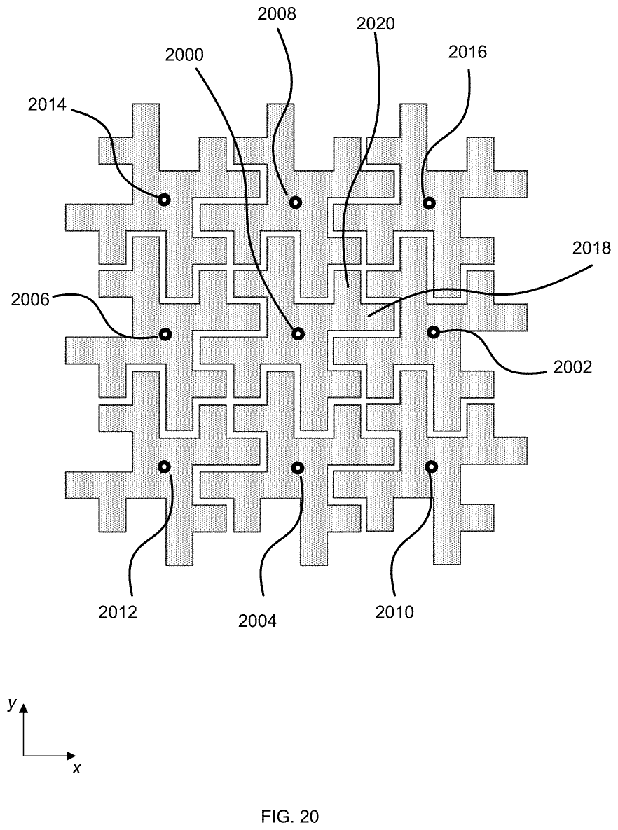

FIG. 20 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of squares on a square grid. Shaped pixel electrodes are positioned with their centers on vertices of squares on a square grid as in FIGS. 1C and 1E.

As shown in FIG. 20, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 2000 has an electrode extension 2018 toward the shaped pixel electrode associated with pixel electrode center 2002. Electrode extension 2018 has a secondary electrode extension 2020 toward pixel electrode center 2008. The shaped pixel electrode associated with pixel electrode center 2000 has a repeat of electrode extension 2018 every 90 degrees toward the shaped pixel electrodes associated with pixel electrode center 2004, pixel electrode center 2006, and pixel electrode center 2008. The branches of the shaped pixel electrode associated with pixel electrode center 2000 interdigitate with electrode extensions from shaped pixel electrodes associated with pixel electrode center 2002, pixel electrode center 2004 pixel electrode center 2006, and pixel electrode center 2008 respectively. The shaped pixel electrodes tile together.

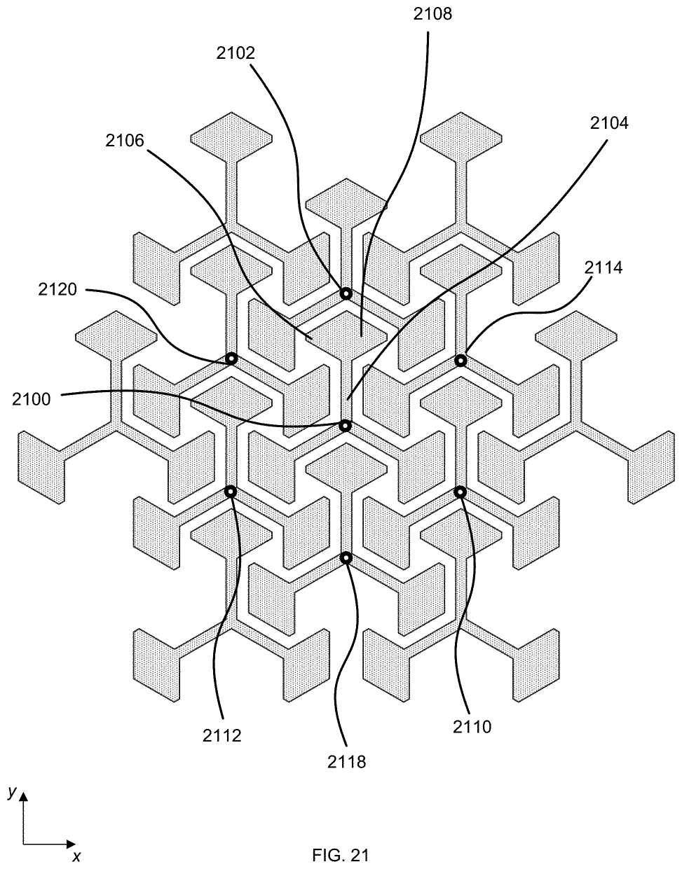

FIG. 21 depicts an embodiment of pixel electrodes according to disclosed techniques. The pixel electrodes are tiled across the detector such that the pixel electrode centers are positioned on vertices of a grid. Vertices of the grid are configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 21, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 2100 has an electrode extension 2104 toward pixel electrode center 2102. The end of electrode extension 2104 branches to the right (right branch 2108) and to the left (left branch 2106) 120 degrees from the body of electrode extension 2104 to form a diamond shape. The shaped pixel electrode associated with pixel electrode center 2100 has a repeat of electrode extension 2104 every 120 degrees toward pixel electrode center 2110 and pixel electrode center 2112. The branches of the shaped pixel electrode associated with pixel electrode center 2100 interdigitate with electrode extensions from shaped pixel electrodes associated with pixel electrode center 2102, pixel electrode center 2110, and pixel electrode center 2112 as well as pixel electrode center 2114, pixel electrode center 2118, and pixel electrode center 2120 respectively. The shaped pixel electrodes tile together.

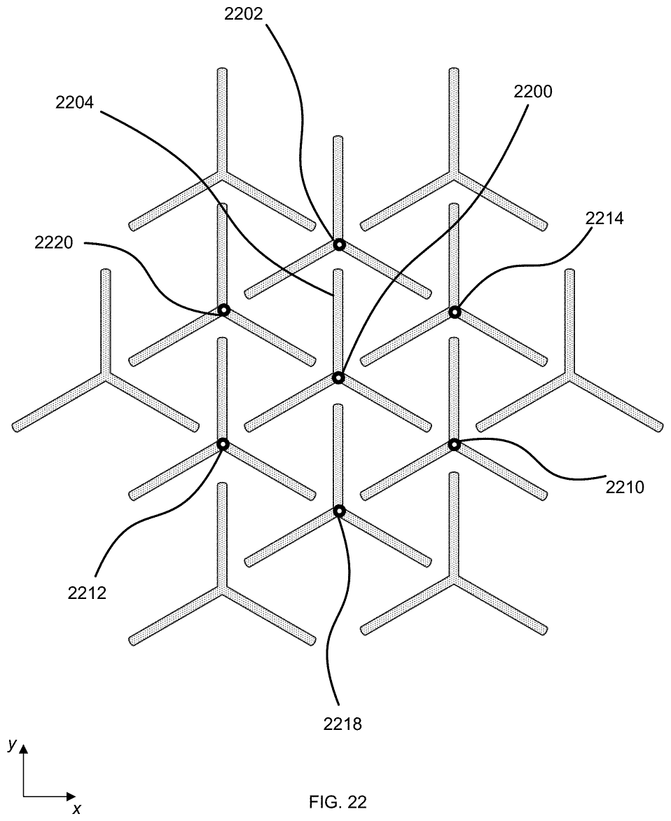

FIG. 22 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. In this particular example, shaped pixel electrodes are positioned with their centers on vertices of equilateral triangles on an equilateral triangular grid as in FIGS. 1B and 1D.

As shown in FIG. 22, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 2200 has an electrode extension 2204 toward pixel electrode center 2202. The shaped pixel electrode associated with pixel electrode center 2200 has a repeat of electrode extension 2204 every 120 degrees toward pixel electrode center 2210 and pixel electrode center 2212. The branches of the shaped pixel electrode associated with pixel electrode center 2200 interdigitate with electrode extensions from shaped pixel electrodes associated with pixel electrode center 2202, pixel electrode center 2210, and pixel electrode center 2212 as well as pixel electrode center 2214, pixel electrode center 2218, and pixel electrode center 2220 respectively. The shaped pixel electrodes tile together.

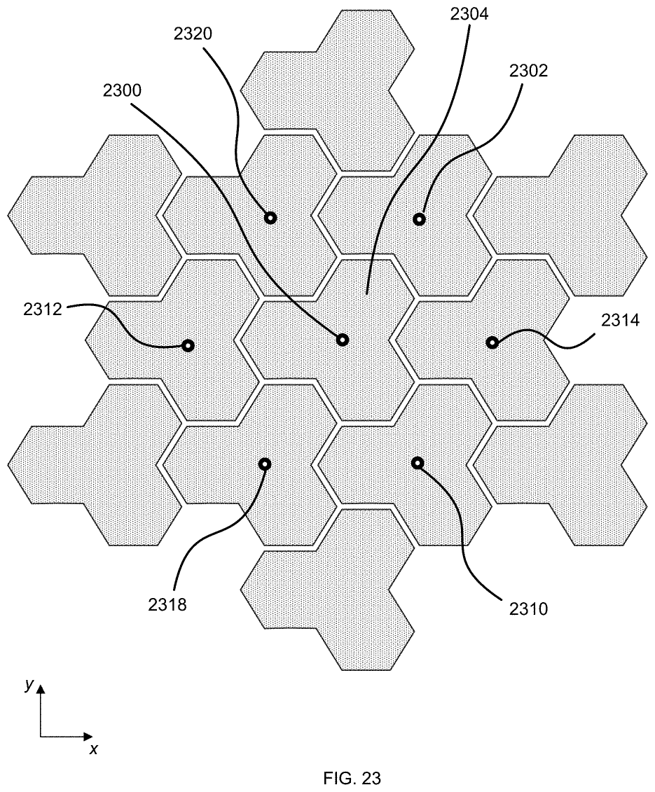

FIG. 23 depicts an embodiment of pixel electrodes according to disclosed techniques. The pixel electrodes are tiled across the detector such that the pixel electrode centers are positioned on vertices of a grid. Vertices of the grid can be configured to form a shape selected from the group consisting of: a parallelogram, a triangle, and a hexagon. Here, the pixel electrode centers are positioned on vertices of equilateral triangles on an equilateral triangular grid. Shaped pixel electrodes are positioned with their centers on vertices of equilateral triangles on an equilateral triangular grid as in FIGS. 1B and 1D.

As shown in FIG. 23, a shaped pixel electrode comprises interdigitating extensions configured to interdigitate with an adjacent neighbor pixel electrode. The extent of the shaped pixel electrode comprises interdigitating extensions configured to interdigitate by branching with interdigitating extensions of an adjacent neighbor pixel electrode. A shaped pixel electrode associated with pixel electrode center 2300 has an electrode extension 2304 toward pixel electrode center 2302. The shaped pixel electrode associated with pixel electrode center 2300 has a repeat of electrode extension 2304 every 120 degrees toward pixel electrode center 2310 and pixel electrode center 2312. The branches of the shaped pixel electrode associated with pixel electrode center 2300 interdigitate with electrode extensions from shaped pixel electrodes associated with pixel electrode center 2302, pixel electrode center 2310, and pixel electrode center 2312 as well as pixel electrode center 2314, pixel electrode center 2318, and pixel electrode center 2320 respectively. The shaped pixel electrodes tile together.

Deposited energy such as a photon absorbed in a solid-state detector generates a cloud of electron-hole pairs in the region of energy deposition where the absorption occurred. The clouds of positive and negative carriers are separated by the voltage across the detector crystal and each cloud drifts toward an electrode. The charge cloud expands outward as it drifts due to carrier diffusion. As the carriers drift toward the electrodes, they induce signals at one or more pixel electrodes in the region. Based on these signals, the best estimate of the energy deposition location where the photon was absorbed is somewhere within the boundaries of the pixel with the highest induced signal. In these detectors, pixel sizes are generally between tens and hundreds of microns on a side.

When the size of the charge cloud is comparable to that of the size of a pixel, the likelihood increases that signals will be induced on multiple pixels in the region. The sum of the signals induced at pixels in the region is a nominal estimate of the energy that was deposited in the semiconductor. In some cases, pixel signals that are less than a threshold are not reported, which reduces the accuracy of the energy estimate formed from the summed pixel values.

The deposited energy and energy deposition location (e.g., location of the photon absorption) can be more accurately determined through an iterative method that employs a forward model (which simulates the size of the charge cloud and its propagation through the detector crystal, culminating in the calculated signal induction at the electrodes) to predict the distribution of pixel signals for a set of potential photon absorptions (e.g. three-dimensional grid of test locations). The iterative method that employs the forward model can be used to estimate, at a minimum, the (x, y) energy deposition location relative to the detector face. In some embodiments, the forward model can be developed so that the iterative routine can also estimate the depth of interaction z and deposited energy E associated with the energy deposition. The initial diameter of the charge cloud is dependent on the energy that is transferred to the detector crystal, and the amount of outward diffusion of the charge cloud is a measure of the distance over which the charge cloud traveled in the electric field created by the applied bias voltage.

A merit function is applied to determine the predicted values most similar to the measured values. Another set of potential points (e.g., test locations) and their respective signals are generated for a smaller grid spacing re-centered around the previous best match location. This process iterates until the estimate converges and a best agreement is found between the measured and predicted values. The sampled location (e.g., test location) with the best agreement between the predicted and measured data becomes the final energy deposition location.

Higher-resolution images can be formed from these final estimated energy deposition locations by rebinning the positions to a finer grid of subpixels. This effectively increases the native resolution of the detector.

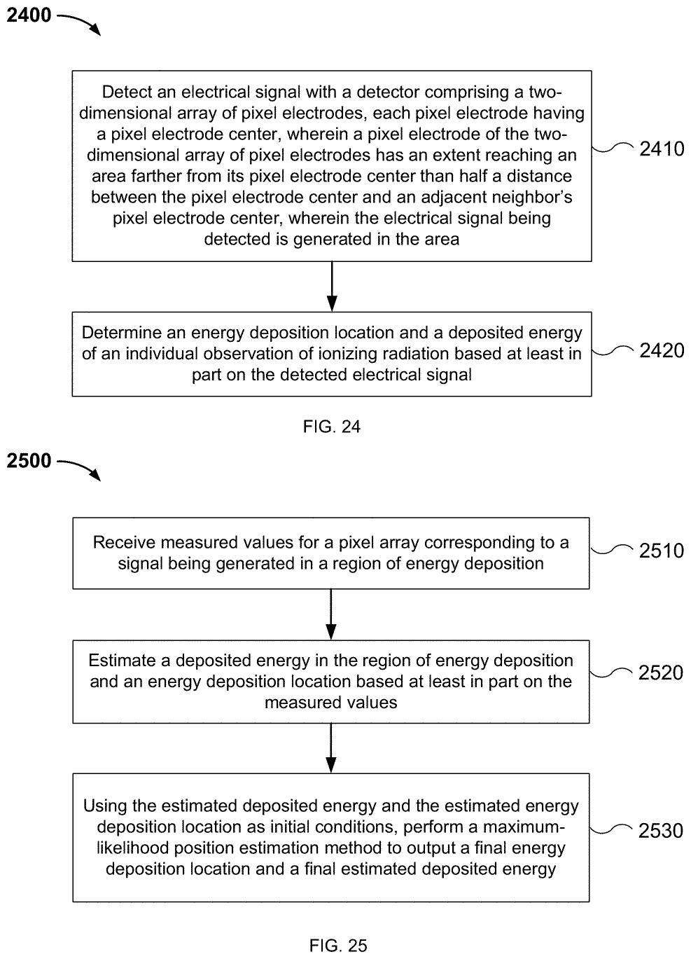

FIG. 24 is a flow diagram illustrating an embodiment of a method 2400 for sub-pixel resolution of an individual observation of ionizing radiation by electrode gerrymandering. In some embodiments, the method 2400 of FIG. 24 is used to determine an energy deposition location (e.g., at 126) as depicted in FIG. 1A.

As shown in FIG. 24, at 2410 the method includes detecting an electrical signal with a detector comprising a two-dimensional array of pixel electrodes, each pixel electrode having a pixel electrode center, wherein a pixel electrode of the two-dimensional array of pixel electrodes has an extent reaching an area farther from its pixel electrode center than half a distance between the pixel electrode center and an adjacent neighbor's pixel electrode center, and wherein the electrical signal being detected is generated in the area. Examples of various two-dimensional arrays of pixel electrodes have been described above with respect to FIGS. 2-23.

At 2420, the method includes determining an energy deposition location and a deposited energy of an individual observation of ionizing radiation based at least in part on the detected electrical signal. The detected electrical signal is induced at the pixel electrode and at least two adjacent neighbor pixel electrodes as charge carriers generated by ionizing radiation drift toward the pixel electrode and the at least two adjacent neighbor pixel electrodes.

The disclosed techniques employ an energy-resolving, spectroscopic, or photon-processing detector or any other detector having an ability to report information related to energy and position. The detector of method 2400 can comprise a hybrid pixel detector comprising a bulk semiconductor crystal patterned with the two-dimensional array of pixel electrodes. The two-dimensional array of pixel electrodes can be coupled to readout electronics. Ionizing radiation deposits energy in the bulk semiconductor crystal and generates charge carriers in an area of energy deposition. A bias voltage is applied across the bulk semiconductor crystal.

In some embodiments, the extent of the pixel electrode is configured to be within a range of an electrical signal generated in a location that is farther from the pixel electrode center than half a distance between the pixel electrode center and an adjacent neighbor's pixel electrode center. In some cases, the electrical signal is induced at the pixel electrode and at least two adjacent neighbor pixel electrodes as the charge carriers generated by the ionizing radiation drift toward the pixel electrode and the at least two adjacent neighbor pixel electrodes.

In some embodiments, the pixel electrodes are tiled across the detector such that the pixel electrode centers are positioned on vertices of a grid. The vertices of the grid can be configured to form a shape selected from the group consisting of: a parallelogram, a triangle, and a hexagon. In some cases, the extent of the pixel electrode comprises interdigitating extensions configured to interdigitate with an adjacent neighbor pixel electrode. For example, interdigitating extensions can be configured to interdigitate by branching or snaking with interdigitating extensions of an adjacent neighbor pixel electrode. Various embodiments of such pixel electrode configurations are described above with respect to FIGS. 2-23.

FIG. 25 is a flow diagram illustrating an embodiment of a method 2500 for determining an energy deposition location and a deposited energy of an individual observation of ionizing radiation based at least in part on a detected electrical signal. In some embodiments, the method 2500 of FIG. 25 can be used to perform step 2420 of FIG. 24, wherein the electrical signal is detected using a detector comprising a two-dimensional array of pixel electrodes as described with respect to FIGS. 2-23.

Returning to FIG. 25, the method 2500 for determining an energy deposition location and a deposited energy includes receiving measured values for a pixel array corresponding to a signal being generated in a region of energy deposition at 2510. In some embodiments, as described for example with respect to FIG. 24, the measured values are received from a detector comprising a two-dimensional array of pixel electrodes, each pixel electrode having a pixel electrode center, wherein a pixel electrode of the two-dimensional array of pixel electrodes has an extent that is farther from its pixel electrode center than half a distance between the pixel electrode center and an adjacent neighbor's pixel electrode center.

In some embodiments (not shown), a method for determining an energy deposition location and a deposited energy of an individual observation of ionizing radiation based at least in part on a detected electrical signal includes receiving measured data comprising a pixel array, each pixel in the pixel array having a measured pixel output value, and selecting a subset of pixels in the pixel array based on measured pixel output values that indicate a signal being generated in a region of energy deposition, the signal having been induced in pixel electrodes corresponding to the selected subset of pixels. In these embodiments, the measured values received for example at 2510 comprise measured pixel output values of the selected subset of pixels. As an example, measured pixel output values from a subset of a pixel array such as 3×3 array of pixels in which an electrical signal is induced in shaped pixel electrodes associated with the 3×3 array of pixels are received.

At 2520, the method includes estimating a deposited energy in the region of energy deposition and an energy deposition location based at least in part on the measured values. In some embodiments, the measured data comprises a pixel array, each pixel in the pixel array having a measured pixel output value. In these embodiments, the measured values comprise the measured pixel output values of a selected subset of pixels. Accordingly, the deposited energy in the region of energy deposition is estimated based at least in part on the measured pixel output values for the selected subset of pixels. For example, a sum of the measured pixel output values can be used to estimate the deposited energy.

Where the measured values comprise measured pixel output values of a selected subset of pixels, the energy deposition location is also estimated based at least in part on the measured pixel output values for the selected subset of pixels and a center-to-center spacing between the pixel electrodes corresponding to the selected subset of pixels. In some embodiments, estimating an energy deposition location comprises estimating an (x, y, z) location. In embodiments where measured values are received from a hybrid pixel detector comprising a bulk semiconductor crystal patterned with the two-dimensional array of pixel electrodes and where the measured values comprise the measured pixel output values of a selected subset of pixels, a weighted centroid of the measured pixel output values is computed as an initial estimate of an (x, y) location of the deposited energy, and half the thickness of the bulk detector is used as an initial estimate of a z location of the deposited energy.

At 2530, the method includes using the estimated deposited energy and the estimated energy deposition location as initial conditions to perform a maximum-likelihood position estimation method to output a final energy deposition location and a final estimated deposited energy. In some cases, the estimated energy deposition location includes an estimated (x, y, z) energy deposition location. A number of different methods for performing a maximum-likelihood position estimation can be used including an exhaustive search, directed search, nested search, subset search, or lookup table. These and other methods of performing a maximum-likelihood position estimation to determine a final energy deposition location and a final estimated deposited energy can be used without limiting the scope of the disclosed techniques. In the example that follows, a maximum-likelihood position estimation method comprises applying a contracting-grid search algorithm and a forward model to predict values for subsequent iterations of the contracting-grid search algorithm to output a final energy deposition location and a final estimated deposited energy upon convergence of the algorithm. An advantage of applying a contracting-grid search algorithm to determine a final energy deposition location and a final estimated deposited energy as described herein is the ability to implement this algorithm in hardware, which can be a difficulty when using other estimation techniques.

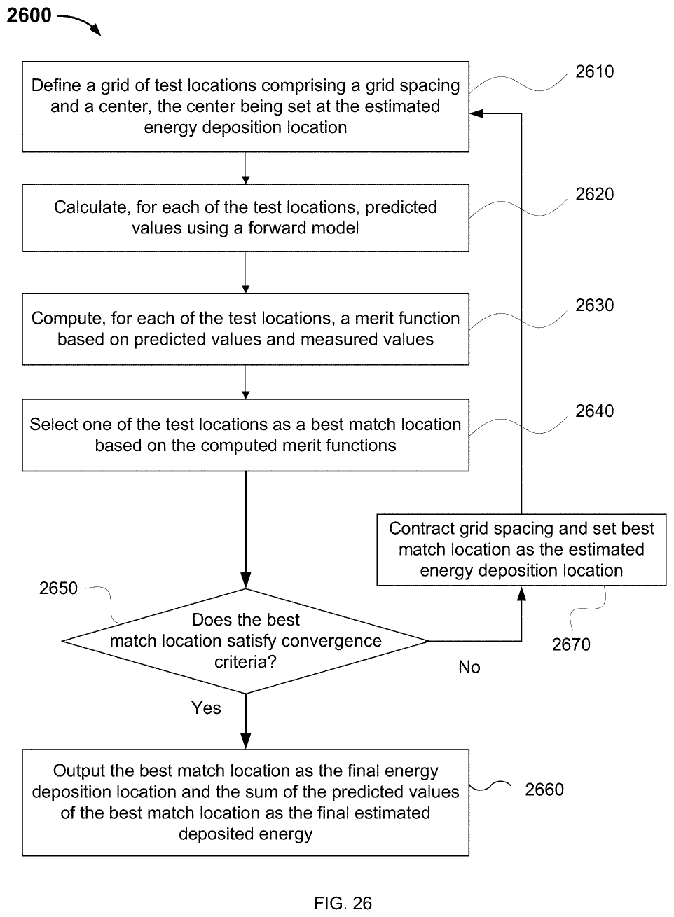

FIG. 26 is a flow diagram illustrating an embodiment of a method 2600 for applying a contracting-grid search algorithm and a forward model to predict values for subsequent iterations of the contracting-grid search algorithm to output a final energy deposition location and a final estimated deposited energy upon convergence of the algorithm. In some embodiments, the method 2600 of FIG. 26 can be used to perform step 2530 of FIG. 25.

At 2610, the method includes defining a three-dimensional grid of test locations comprising a grid spacing and a center, the center being set at the estimated energy deposition location. In some cases, the location includes an estimated (x, y, z) energy deposition location.

At 2620, the method includes calculating, for each of the test locations, predicted values using the forward model. The forward model can simulate signals induced in electrodes that have an extent in the region of the energy deposition. The forward model can include or use components that represent physical processes to calculate the predicted pixel output values.

At 2630, the method includes computing, for each of the test locations, a merit function based on the predicted values and the measured values.

At 2640, the method includes selecting one of the test locations as a best match location based on the computed merit functions.

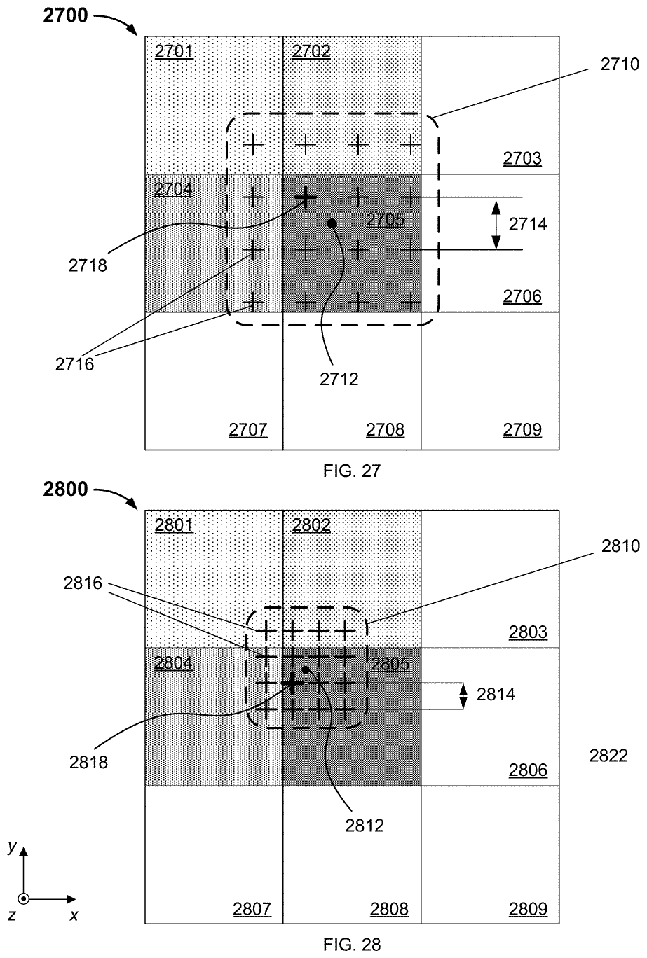

At 2650, the method determines whether the best match location satisfies a convergence criteria. If the best match location satisfies the convergence criteria based on the determination, the method outputs the best match location as the final energy deposition location and the sum of the predicted values of the best match location is output as the estimated deposited energy at 2660. If the best match location does not satisfy the convergence criteria based on the determination, the method performs a next iteration of the contracting-grid search algorithm by contracting the grid spacing and setting the best match location as the estimated energy deposition location at 2670. Setting the best match location as the estimated energy deposition location for the next iteration effectively centers the contracted grid at the best match location. To contract the grid, the grid spacing is decreased by a factor. For example, a factor of two can be used to decrease the grid spacing thereby resulting in resampling the spacing at half grid. A visual depiction of a two-dimensional subset of a three-dimensional grid of test locations used in applying a contracting-grid search algorithm is provided in FIGS. 27 and 28.

Steps 2610 through 2670 are repeated using the contracted grid spacing and the best match location as the grid center to provide test locations for the next iteration of the algorithm. This cycle continues until one of the test locations selected as the best match location satisfies the convergence criteria and is output as the final energy deposition location and the sum of the predicted values of the best match location is output as the final estimated deposited energy at 2660.

In embodiments where measured data comprising a pixel array is received, each pixel in the pixel array is represented by a measured pixel output value. In these cases, a subset of pixels in the pixel array are selected based on measured pixel output values that indicate a signal being generated in a region of energy deposition, the signal having been induced in pixel electrodes corresponding to the selected subset of pixels. In these embodiments, the measured values received comprise measured pixel output values of the selected subset of pixels and the predicted values comprise predicted pixel output values for the selected subset of pixels. Accordingly, the predicted values calculated for each of the test locations using the forward model (e.g., step 2620) comprise predicted pixel output values for the selected subset of pixels.

In some embodiments, the merit function is applied to compare calculations of predicted values compared to measured values, and in cases where the predicted values comprise predicted pixel output values and the measured values comprise measured pixel output values for a selected subset of pixels, the predicted pixel output values are scaled or normalized in order to compare them to the measured pixel output values.

FIGS. 27 and 28 are visual depictions of a two-dimensional subset of a three-dimensional grid of test locations used in applying a contracting-grid search algorithm as described herein.

FIG. 27 shows a two-dimensional subset of a three-dimensional grid of test locations (e.g., shown at 2710) superimposed on a subset of pixels in a pixel array (e.g., shown at 2700) based on measured pixel output values. The three-dimensional grid of test locations extends into and out of the page of FIG. 27 in the ±z direction as indicated by the axes. The measured pixel output values indicate a signal being generated in a region of energy deposition, the signal having been induced in pixel electrodes corresponding to the selected subset of pixels. The measured values comprise the measured pixel output values of the selected subset of pixels. The subset of pixels comprises a 2×2 subset (e.g., consisting of pixels 2701, 2702, 2704, and 2705) of a larger 3×3 pixel array (e.g., consisting of pixels shown at 2701-2709). The darker shading in the pixel, the larger the measured value or intensity of the signal being detected. Pixel 2705 has the darkest shading and the highest measured pixel output value in the subset. Pixel 2704 has a lighter shading than pixel 2705 corresponding to a lower measured pixel output value than pixel 2705. Pixel 2702 is lighter still, as is pixel 2701, with the lightest shading and lowest measured pixel output value in the subset. The other pixels (e.g., pixels shown at 2703, 2706, 2707, 2708 and 2709) in the 3×3 array are unshaded, indicating a zero output value (i.e., no reported induced signal or zeroed out as boundary conditions for the algorithm).

The three-dimensional grid of test locations 2710 is defined by a center 2712 and a grid spacing 2714. The grid is initially centered at the estimated energy deposition location and a grid spacing is determined based on the number of sample points in the grid and the starting search region (e.g., a square area with dimensions specified by the center-to-center pixel electrode spacing define the xy grid, and the thickness of the detector bulk defines the grid extent in the z direction). In some embodiments, an initial estimate for an energy deposition (x, y, z) location is provided by taking a weighted centroid of the measured pixel output values as an estimate of the (x, y) location of the deposited energy, and half the thickness of the bulk detector as an initial estimate of a z location of the deposited energy.

The grid 2710 comprises a 4×4 grid of test locations that is a subset of a 4×4×4 grid of test locations denoted in FIG. 27 by a 4×4 array of crosshairs (as an example, a couple of test locations are shown at 2716). For each of these 16 test locations in the 4×4 array, predicted pixel output values are calculated using a forward model. A merit function is computed for each of the 64 test locations based on the predicted values and the measured values, which in this case are predicted pixel output values and measured pixel output values. One of the test locations is selected as the best match location based on the computed merit functions. In this case, test location 2718 is selected as the best match location based on a calculation of its merit function. This means that the predicted values for test location 2718 using the forward model are the most similar to or most closely match the measured values (in this case, corresponding to the measured pixel output values of the shaded pixels 2705, 2704, 2702, and 2701). If the best match location, in this case, test location 2718, satisfies a convergence criteria, the best match location (test location 2718) is outputted as the final energy deposition location and the sum of the predicted values of the best match location is output as the final estimated deposited energy. If the best match location does not satisfy the convergence criteria, a next iteration of the contracting-grid search algorithm is performed.

FIG. 28 is a visual depiction of a next iteration of the grid-contracting search algorithm using a contracted grid. The grid 2810 of test locations for a next iteration is shown superimposed on a subset of pixels in a pixel array (e.g., shown at 2800) based on measured pixel output values. The subset of pixels comprises a 2×2 subset (e.g., consisting of pixels 2801, 2802, 2804, and 2805) of a larger 3×3 pixel array (e.g., consisting of pixels shown at 2801-2809). As in FIG. 27, the darker shading in the pixel, the larger the measured value or intensity of the signal being detected. Pixel 2805 has the darkest shading and the highest measured pixel output value. Pixel 2804 has a lighter shading than pixel 2805 corresponding to a lower measured pixel output value than pixel 2805. Pixel 2802 is lighter still, as is pixel 2801, with the lightest shading and lowest measured pixel output value. The other pixels (e.g., pixels shown at 2803, 2806, 2807, 2808 and 2809) in the 3×3 array are unshaded, indicating a zero output value (i.e., no reported induced signal or zeroed out as boundary conditions for the algorithm).

A next iteration is performed by contracting the current grid spacing (e.g., grid spacing 2714 of FIG. 27) and setting the best match location as the estimated energy deposition location (test location 2718 of FIG. 27). In this case, grid 2714 is contracted by decreasing grid spacing by a factor of 2 to define a contracted 4×4 grid 2810 of test locations (denoted by crosshairs in FIG. 28). As shown in FIG. 28, contracted grid 2810 is defined by grid spacing 2814, which in this case is half the grid spacing 2714—thus the test locations are resampled at half of the previous grid spacing. The contracted grid 2810 defined by grid spacing 2814 is centered at the best match location of the previous iteration (test location 2718 of FIG. 27), which is shown in FIG. 28 at 2812. The steps described with respect to FIG. 27 using grid 2710 are repeated using a grid defined by the contracted grid spacing 2814 and grid center at 2812 (corresponding to the best match location/test location 2718 of FIG. 27) to provide test locations until one of the test locations selected as the best match location satisfies the convergence criteria.

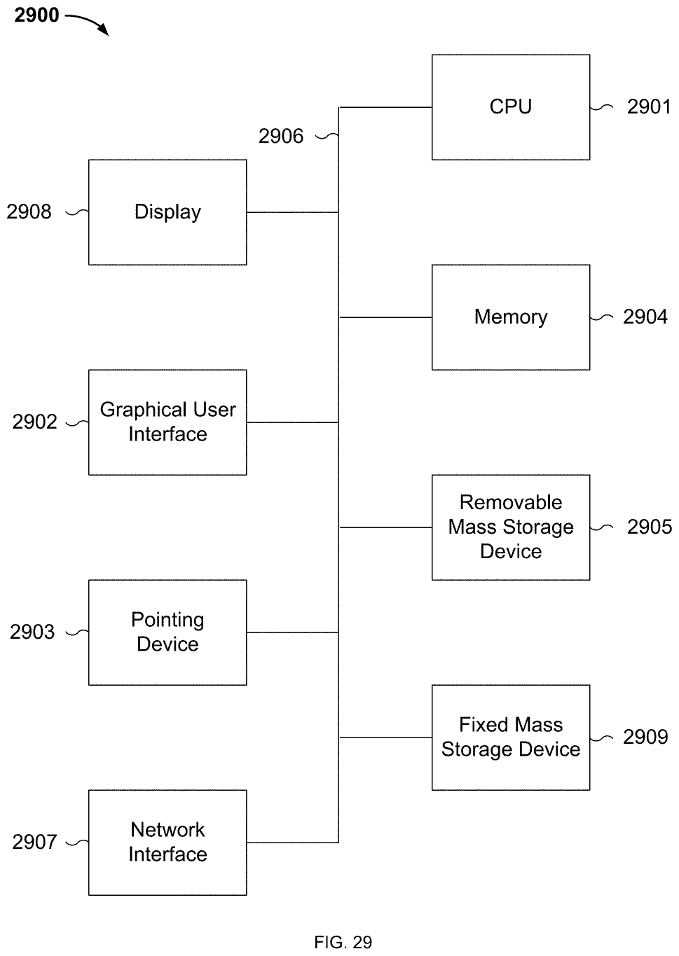

FIG. 29 is a block diagram of a computer system 2900 used in some embodiments to perform sub-pixel resolution of an individual observation of ionizing radiation by electrode gerrymandering. In particular, FIG. 29 illustrates one embodiment of a general purpose computer system. Other computer system architectures and configurations can be used for carrying out the processing of the disclosed technique. Computer system 2900, made up of various subsystems described below, includes at least one microprocessor subsystem (also referred to as a central processing unit, or CPU) 2901. That is, CPU 2901 can be implemented by a single-chip processor or by multiple processors. In some embodiments, CPU 2901 is a general purpose digital processor which controls the operation of the computer system 2900. Using instructions retrieved from memory 2904, the CPU 2901 controls the reception and manipulation of input data, and the output and display of data on output devices.

CPU 2901 is coupled bi-directionally with memory 2904 which can include a first primary storage, typically a random access memory (RAM), and a second primary storage area, typically a read-only memory (ROM). As is well known in the art, primary storage can be used as a general storage area and as scratch-pad memory, and can also be used to store input data and processed data. It can also store programming instructions and data, in the form of data objects and text objects, in addition to other data and instructions for processes operating on CPU 2901. Also as is well known in the art, primary storage typically includes basic operating instructions, program code, data, and objects used by the CPU 2901 to perform its functions. Primary storage devices 2904 may include any suitable computer-readable storage media, described below, depending on whether, for example, data access needs to be bi-directional or uni-directional. CPU 2901 can also directly and very rapidly retrieve and store frequently needed data in a cache memory (not shown).

A removable mass storage device 2905 provides additional data storage capacity for the computer system 2900, and is coupled either bi-directionally (read/write) or uni-directionally (read only) to CPU 2901. Storage device 2905 may also include computer-readable media such as magnetic tape, flash memory, signals embodied on a carrier wave, PC-CARDS, portable mass storage devices, holographic storage devices, and other storage devices. A fixed mass storage 2909 can also provide additional data storage capacity. The most common example of mass storage 2909 is a hard disk drive. Mass storages 2905, 2909 generally store additional programming instructions, data, and the like that typically are not in active use by the CPU 2901. It will be appreciated that the information retained within mass storages 2905, 2909 may be incorporated, if needed, in standard fashion as part of primary storage 2904 (e.g., RAM) as virtual memory.

In addition to providing CPU 2901 access to storage subsystems, bus 2906 can be used to provide access to other subsystems and devices as well. In the described embodiment, these can include a display 2908, a network interface 2907, a graphical user interface 2902, and a pointing device 2903, as well as an auxiliary input/output device interface, a sound card, speakers, and other subsystems as needed. The pointing device 2903 may be a mouse, stylus, track ball, or tablet, and is useful for interacting with graphical user interface 2902.

In some embodiments, measured values for a pixel array corresponding to a signal being generated in a region of energy deposition are received or obtained by the computer system 2900 and CPU 2901 is configured to estimate a deposited energy in the region of energy deposition and an energy deposition location based at least in part on the measured values. Using the estimated deposited energy and the estimated energy deposition location as initial conditions, CPU 2901 can be configured to perform a maximum-likelihood position estimation method to output a final energy deposition location and a final estimated deposited energy. The estimated energy deposition location can include an estimated (x, y, z) energy deposition location. Performing a maximum-likelihood position estimation method can comprise applying a contracting-grid search algorithm and a forward model to predict values for subsequent iterations of the contracting-grid search algorithm to output a final energy deposition location and a final estimated deposited energy upon convergence of the algorithm. The forward model can simulate the signal being generated in the region of energy deposition.

In some embodiments, CPU 2901 is configured to apply a contracting-grid search algorithm and a forward model to predict values for subsequent iterations of the contracting-grid search algorithm to output a final energy deposition location and a final estimated deposited energy upon convergence of the algorithm. In some cases CPU 2901 is configured to: (a) define a three-dimensional grid of test locations comprising a grid spacing and a center, the center being set at the estimated energy deposition location; (b) calculate, for each of the test locations, predicted values using the forward model; (c) compute, for each of the test locations, a merit function based on the predicted values and the measured values; (d) select one of the test locations as a best match location based on the computed merit functions; (e) output the best match location as the final energy deposition location and the sum of the predicted values of the best match location is output as the final estimated deposited energy if the best match location satisfies a convergence criteria; and (f) if the best match location does not satisfy the convergence criteria, perform a next iteration of the contracting-grid search algorithm by contracting the grid spacing and setting the best match location as the estimated energy deposition location and then repeating steps (a) through (f) using the contracted grid spacing and the best match location as the grid center to provide test locations until one of the test locations selected as the best match location satisfies the convergence criteria. CPU 2901 is configured to process or send the output (e.g., the final energy deposition location and/or the final estimated deposited energy) to be displayed on display 2908. Graphical user interface 2902 is configured to display the final energy deposition location and the final estimated deposited energy.

In some embodiments, CPU 2901 is configured to receive measured data comprising a pixel array. Each pixel in the pixel array has a measured pixel output value. CPU 2901 is further configured to select a subset of pixels in the pixel array based on measured pixel output values that indicate a signal being generated in a region of energy deposition, the signal having been induced in pixel electrodes corresponding to the selected subset of pixels.

In some embodiments, the measured values are received by CPU 2901 from a detector comprising a two-dimensional array of pixel electrodes, each pixel electrode having a pixel electrode center, wherein a pixel electrode of the two-dimensional array of pixel electrodes has an extent that is farther from its pixel electrode center than half a distance between the pixel electrode center and an adjacent neighbor's pixel electrode center. In some cases, the measured values comprise the measured pixel output values of the selected subset of pixels. The deposited energy in the region of energy deposition is estimated based at least in part on the measured pixel output values. The energy deposition location is estimated based at least in part on the measured pixel output values for the selected subset of pixels and a center-to-center spacing between the pixel electrodes corresponding to the selected subset of pixels. The predicted values comprise predicted pixel output values for the selected subset of pixels.

The network interface 2907 allows CPU 2901 to be coupled to another computer, computer network, or telecommunications network using a network connection as shown. Through the network interface 2907, it is contemplated that the CPU 2901 might receive information, e.g., data objects or program instructions, from another network, or might output information to another network in the course of performing the above-described method steps. Information, often represented as a sequence of instructions to be executed on a CPU, may be received from and outputted to another network, for example, in the form of a computer data signal embodied in a carrier wave. An interface card or similar device and appropriate software implemented by CPU 2901 can be used to connect the computer system 2900 to an external network and transfer data according to standard protocols. That is, method embodiments of the disclosed technique may execute solely upon CPU 2901, or may be performed across a network such as the Internet, intranet networks, or local area networks, in conjunction with a remote CPU that shares a portion of the processing. Additional mass storage devices (not shown) may also be connected to CPU 2901 through network interface 2907.

An auxiliary I/O device interface (not shown) can be used with computer system 2900. The auxiliary I/O device interface can include general and customized interfaces that allow the CPU 101 to send and receive data from other devices such as detectors, microphones, touch-sensitive displays, transducer card readers, tape readers, voice or handwriting recognizers, biometrics readers, cameras, portable mass storage devices, and other computers.

The computer system shown in FIG. 29 is but an example of a computer system suitable for use with the disclosed technique. Other computer systems suitable for use with the disclosed technique may include additional or fewer subsystems. In addition, bus 2906 is illustrative of any interconnection scheme serving to link the subsystems. Other computer architectures having different configurations of subsystems may also be utilized.

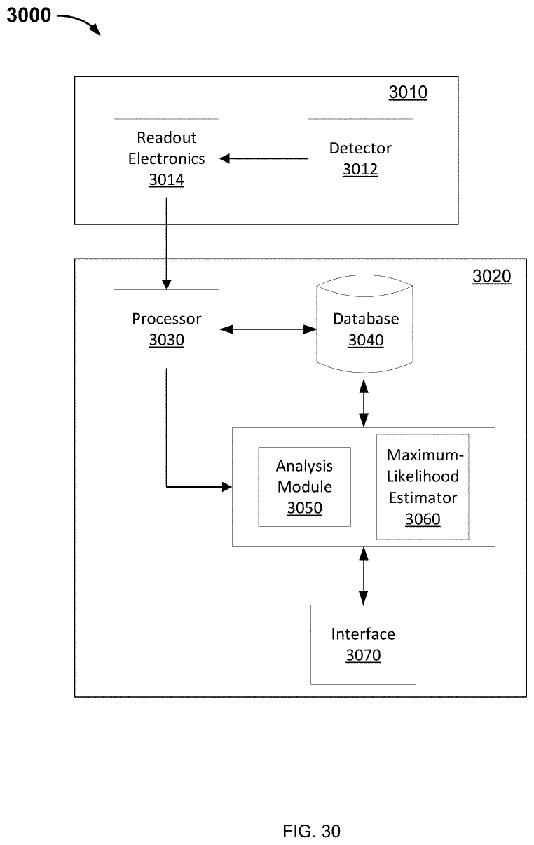

FIG. 30 is a block diagram of a system 3000 used in some embodiments for sub-pixel resolution of an individual observation of ionizing radiation by electrode gerrymandering.

As shown in FIG. 30, the system 3000 comprises a detection system 3910 and a computer system 3920. In some embodiments, computer system 3020 comprises computer system 2900 of FIG. 29. In the example shown, detection system 3010 includes a device comprising a Detector 3012 and Readout Electronics 3014. Techniques as disclosed herein (e.g., detection system 3910) employ an energy-resolving, spectroscopic, or photon-processing detector or any other detector having an ability to report information related to energy and position. In some embodiments, Detector 3012 comprises a two-dimensional array of pixel electrodes, each pixel electrode having a pixel electrode center, wherein a pixel electrode of the two-dimensional array of pixel electrodes has an extent that is farther from its pixel electrode center than half a distance between the pixel electrode center and an adjacent neighbor's pixel electrode center. In some cases, the detector comprises a hybrid pixel detector comprising a bulk semiconductor crystal patterned with the two-dimensional array of pixel electrodes. The two-dimensional array of pixel electrodes is coupled to Readout Electronics 3014. Ionizing radiation deposits energy in the bulk semiconductor crystal and generates charge carriers in an area of energy deposition. A bias voltage is applied across the bulk semiconductor crystal.

In some embodiments, the extent of the pixel electrode is configured to be within a range of an electrical signal generated in a location that is farther from the pixel electrode center than half a distance between the pixel electrode center and an adjacent neighbor's pixel electrode center. In some cases, the electrical signal is induced at the pixel electrode and at least two adjacent neighbor pixel electrodes as the charge carriers generated by the ionizing radiation drift toward the pixel electrode and the at least two adjacent neighbor pixel electrodes.

In some embodiments, the pixel electrodes are tiled across the detector such that the pixel electrode centers are positioned on vertices of a grid. The vertices of the grid can be configured to form a shape selected from the group consisting of: a parallelogram, a triangle, and a hexagon. The extent of the pixel electrode can comprise interdigitating extensions configured to interdigitate with an adjacent neighbor pixel electrode, for example, by branching or snaking with interdigitating extensions of an adjacent neighbor pixel electrode. The extensions can also be configured to repeat when rotated a by a number of degrees (e.g., 90, 120, or 180 degrees). Various embodiments of pixel electrode configurations and two-dimensional arrays of pixel electrodes configured to sense an electrical signal induced at the pixel electrode and at least two adjacent neighbor pixel electrodes are described herein with respect to FIGS. 2-23.

Returning to FIG. 30, system 3000 further comprises a computer system 3020 that includes at least one processor (e.g., Processor 3030) and a memory coupled with the processor (e.g., Database 3040) along with modules (e.g., Analysis Module 3050, Maximum-Likelihood Estimator 3060) configured to execute instructions provided to the processor from the memory. An interface (e.g., Interface 3060) provides an ability for a user to interact with computer system 3020 and to receive an output from the computer system 3020.

An electrical signal induced at a pixel electrode and at least two adjacent neighbor pixel electrodes in the two-dimensional array of pixel electrodes (e.g., in Detector 3012) is processed and reported by Readout Electronics 3014, which provides measured values for the pixel array that correspond to the electrical signal being generated in a region of energy deposition. Measured values are received by computer system 3020, and can be processed (e.g., by Processor 3030) and stored (e.g., in Database 3050). Analysis Module 3050 receives the measured values and estimates a deposited energy in the region of energy deposition and an energy deposition location based at least in part on the measured values. In some cases, the estimated energy deposition location includes an estimated (x, y, z) energy deposition location. Using the estimated deposited energy and the estimated energy deposition location from Analyses Module 3050 as initial conditions, Maximum-Likelihood Estimator 3060 performs a maximum-likelihood position estimation method to output a final energy deposition location and a final estimated deposited energy (e.g., provided as an output and received via Interface 3070).

In some embodiments, Maximum-Likelihood Estimator 3060 is configured to perform a maximum-likelihood position estimation method by applying a contracting-grid search algorithm and a forward model to predict values for subsequent iterations of the contracting-grid search algorithm to output a final energy deposition location and a final estimated deposited energy upon convergence of the algorithm. To apply the contracting-grid algorithm using the forward model, Maximum-Likelihood Estimator 3060 is configured to: define a three-dimensional grid of test locations comprising a grid spacing and a center, the center being set at the estimated (x, y, z) energy deposition location (e.g., provided by Analysis Module 3050) and to calculate, for each of the test locations in the grid, predicted values using the forward model. The forward model simulates the signal being generated in the region of energy deposition. In some cases, the forward model includes or uses components that represent physical processes to calculate the predicted pixel output values. Maximum-Likelihood Estimator 3060 is further configured to compute, for each of the test locations, a merit function based on the predicted values and the measured values and to select one of the test locations as a best match location based on the computed merit functions.

Maximum-Likelihood Estimator 3060 is configured to determine whether the best match location satisfies a convergence criteria. If the best match location satisfies the convergence criteria based on the determination, computer system 3020 outputs the best match location as the final energy deposition location and outputs the sum of the predicted values of the best match location as the final estimated deposited energy(e.g., via Interface 3060). If the best match location does not satisfy the convergence criteria based on the determination, Maximum-Likelihood Estimator 3060 performs a next iteration of the contracting-grid search algorithm by contracting the grid spacing and setting the best match location as the estimated energy deposition location (i.e. as the center of the grid for the next iteration of computations). The grid spacing can be decreased or contracted by a factor. A factor of two can be used to decrease or contract the grid spacing thereby resulting in resampling the spacing at half grid. A visual depiction of one iteration of the contracting grid algorithm is provided in FIG. 27. A visual depiction of a subsequent iteration of the contracting grid algorithm is provided in FIG. 28.

Maximum-Likelihood Estimator 3060 is configured to repeat the steps of: (i) defining a current three-dimensional grid of test locations centered at the current estimated (x, y, z) energy deposition location (i.e., the best match location selected as the estimated energy deposition location in the previous iteration); (ii) calculating predicted values using the forward model for each test location on the current grid; (iii) computing a merit function based on the predicted and measured values for each test location on the current grid; (iv) selecting one of the test locations of the current grid as the best match location based on the computed merit functions; (v) applying a convergence criteria and determining whether the best match location satisfies the convergence criteria; (vi) returning the best match location as the final energy deposition location and returning the sum of the predicted values of the best match location as the final estimated deposited energy if the convergence criteria is met; and otherwise (vii) performing a next iteration of the algorithm using a contracted grid spacing and centering the contracted grid at the most recently calculated best match location (i.e., by setting the best match location as the estimated energy deposition location for a next iteration). This cycle of steps continues using a re-centered contracting grid with each iteration until one of the test locations selected as the best match location satisfies the convergence criteria and is output as the final energy deposition location along with the sum of the predicted values corresponding to the best match location as the final estimated deposited energy by computer system 3020 (e.g., via Interface 3060).

In some embodiments, computer system 3020 receives measured data from detection system 3010 (e.g., from Readout Electronics 3014). The measured data comprises a pixel array, each pixel in the pixel array having a measured pixel output value. Analysis Module 3050 is configured to select a subset of pixels in the pixel array based on measured pixel output values that indicate a signal being generated in a region of energy deposition, the signal having been induced in pixel electrodes (e.g., in the pixel array of Detector 3012) corresponding to the selected subset of pixels. In these cases, the measured values comprise the measured pixel output values of the selected subset of pixels. Analysis Module 3050 is configured to estimate the deposited energy in the region of energy deposition based at least in part on the measured pixel output values for the selected subset of pixels. Analysis Module 3050 is also configured to estimate the energy deposition location based at least in part on the measured pixel output values for the selected subset of pixels and a center-to-center spacing between the pixel electrodes corresponding to the selected subset of pixels. The estimated energy deposition location includes an estimated (x, y, z) energy deposition location. Additionally, the predicted values predicted by the forward model comprise predicted pixel output values for the selected subset of pixels.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A device for sub-pixel resolution of an individual observation of ionizing radiation by electrode gerrymandering, the device comprising:
a detector comprising a two-dimensional array of pixel electrodes, each pixel electrode having a pixel electrode center,
wherein a pixel electrode of the two-dimensional array of pixel electrodes has an extent that is farther from its pixel electrode center than half a distance between the pixel electrode center and an adjacent neighbor's pixel electrode center.

2. The device of claim 1, wherein:
the detector comprises a hybrid pixel detector comprising a bulk semiconductor crystal patterned with the two-dimensional array of pixel electrodes;
the two-dimensional array of pixel electrodes is coupled to readout electronics;
ionizing radiation deposits energy in the bulk semiconductor crystal and generates charge carriers in an area of energy deposition;
a bias voltage is applied across the bulk semiconductor crystal; and
the extent of the pixel electrode is configured to be within a range of an electrical signal generated in a location that is farther from the pixel electrode center than half a distance between the pixel electrode center and an adjacent neighbor's pixel electrode center.

3. The device of claim 1, wherein:
the detector comprises a hybrid pixel detector comprising a bulk semiconductor crystal patterned with the two-dimensional array of pixel electrodes;
the two-dimensional array of pixel electrodes is coupled to readout electronics;
ionizing radiation deposits energy in the bulk semiconductor crystal and generates charge carriers in an area of energy deposition;
a bias voltage is applied across the bulk semiconductor crystal;
the extent of the pixel electrode is configured to be within a range of an electrical signal generated in a location that is farther from the pixel electrode center than half a distance between the pixel electrode center and an adjacent neighbor's pixel electrode center; and
the electrical signal is induced at the pixel electrode and at least two adjacent neighbor pixel electrodes as the charge carriers generated by the ionizing radiation drift toward the pixel electrode and the at least two adjacent neighbor pixel electrodes.

4. The device of claim 1, wherein:
the detector comprises a hybrid pixel detector comprising a bulk semiconductor crystal patterned with the two-dimensional array of pixel electrodes;
the two-dimensional array of pixel electrodes is coupled to readout electronics;
ionizing radiation deposits energy in the bulk semiconductor crystal and generates charge carriers in an area of energy deposition;
a bias voltage is applied across the bulk semiconductor crystal;
the extent of the pixel electrode is configured to be within a range of an electrical signal generated in a location that is farther from the pixel electrode center than half a distance between the pixel electrode center and an adjacent neighbor's pixel electrode center; and
the pixel electrodes are tiled across the detector such that the pixel electrode centers are positioned on vertices of a grid.

5. The device of claim 4, wherein the vertices of the grid are configured to form a shape selected from the group consisting of: a parallelogram, a triangle, and a hexagon.

6. The device of claim 1, wherein the extent of the pixel electrode comprises interdigitating extensions configured to interdigitate with an adjacent neighbor pixel electrode.

7. The device of claim 1, wherein the extent of the pixel electrode comprises interdigitating extensions configured to interdigitate by branching or snaking with interdigitating extensions of an adjacent neighbor pixel electrode, the interdigitating extensions being configured to repeat when rotated a number of degrees selected from the group consisting of: 90 degrees, 120 degrees, and 180 degrees.

8. The device of claim 1, wherein the extent of the pixel electrode comprises interdigitating extensions configured to interdigitate with an adjacent neighbor pixel electrode, the interdigitating extensions being configured to enable the extent of the pixel electrode to reach an area of an adjacent neighbor pixel electrode, the area being farther from the pixel electrode center than half a distance between the pixel electrode center and the adjacent neighbor's pixel electrode center.

9. The device of claim 1, wherein the extent of the pixel electrode comprises interdigitating extensions configured to interdigitate with an adjacent neighbor pixel electrode, the interdigitating extensions being configured to enable the pixel electrode to sense an electrical signal generated in an area of an adjacent neighbor pixel electrode, the area being farther from the pixel electrode center than half a distance between the pixel electrode center and the adjacent neighbor's pixel electrode center.

10. A method for sub-pixel resolution of an individual observation of ionizing radiation by electrode gerrymandering, the method comprising:
detecting an electrical signal with a detector comprising a two-dimensional array of pixel electrodes, each pixel electrode having a pixel electrode center,
wherein a pixel electrode of the two-dimensional array of pixel electrodes has an extent reaching an area farther from its pixel electrode center than half a distance between the pixel electrode center and an adjacent neighbor's pixel electrode center, and
wherein the electrical signal being detected is generated in the area; and
determining an energy deposition location and a deposited energy of an individual observation of ionizing radiation based at least in part on the detected electrical signal.

11. The method of claim 10, wherein:
the detector comprises a hybrid pixel detector comprising a bulk semiconductor crystal patterned with the two-dimensional array of pixel electrodes, each pixel electrode having a pixel electrode center, the pixel electrodes being tiled across the detector such that the pixel electrode centers are positioned on vertices of a grid, and the two-dimensional array of pixel electrodes being coupled to readout electronics;
ionizing radiation deposits energy in the bulk semiconductor crystal and generates charge carriers in an area of energy deposition;
a bias voltage is applied across the bulk semiconductor crystal;
the extent of the pixel electrode is configured to be within a range of the electrical signal; and
the detected electrical signal is induced at the pixel electrode and at least two adjacent neighbor pixel electrodes as charge carriers generated by the ionizing radiation drift toward the pixel electrode and the at least two adjacent neighbor pixel electrodes.

12. The method of claim 10, wherein the extent of the pixel electrode comprises interdigitating extensions configured to interdigitate with an adjacent neighbor pixel electrode, the interdigitating extensions being configured to enable the pixel electrode to sense an electrical signal generated in an area of an adjacent neighbor pixel electrode, the area being farther from the pixel electrode center than half a distance between the pixel electrode center and the adjacent neighbor's pixel electrode center.

13. The method of claim 10, wherein determining an energy deposition location and a deposited energy of an individual observation of ionizing radiation based at least in part on the detected electrical signal comprises:
receiving measured values for a pixel array corresponding to a signal being generated in a region of energy deposition;
estimating a deposited energy in the region of energy deposition and an energy deposition location based at least in part on the measured values; and
using the estimated deposited energy and the estimated energy deposition location as initial conditions, performing a maximum-likelihood position estimation method to output a final energy deposition location and a final estimated deposited energy.

14. The method of claim 13, wherein performing a maximum-likelihood position estimation method comprises applying a contracting-grid search algorithm and a forward model to predict values for subsequent iterations of the contracting-grid search algorithm to output a final energy deposition location and a final estimated deposited energy upon convergence of the algorithm, including by:
(a) defining a three-dimensional grid of test locations comprising a grid spacing and a center, the center being set at the estimated energy deposition location;
(b) calculating, for each of the test locations, predicted values using the forward model;
(c) computing, for each of the test locations, a merit function based on the predicted values and the measured values;
(d) selecting one of the test locations as a best match location based on the computed merit functions;
(e) if the best match location satisfies a convergence criteria, outputting the best match location as the final energy deposition location and outputting the sum of the predicted values corresponding to the best match location as the final estimated deposited energy; and
(f) if the best match location does not satisfy the convergence criteria, performing a next iteration of the contracting-grid search algorithm by contracting the grid spacing and setting the best match location as the estimated energy deposition location and then repeating steps (a) through (f) using the contracted grid spacing and the best match location as the grid center to provide test locations until one of the test locations selected as the best match location satisfies the convergence criteria.

15. The method of claim 14, wherein the forward model simulates the signal being generated in the region of energy deposition.

16. A system for determining an energy deposition location and a deposited energy of an individual observation of ionizing radiation, the system comprising a processor and a memory coupled with the processor, wherein the memory is configured to provide the processor with instructions that when executed cause the processor to:
receive measured values for a pixel array corresponding to a signal being generated in a region of energy deposition;
estimate a deposited energy in the region of energy deposition and an energy deposition location based at least in part on the measured values; and
using the estimated deposited energy and the estimated energy deposition location as initial conditions, perform a maximum-likelihood position estimation method to output a final energy deposition location and a final estimated deposited energy.

17. The system of claim 16, wherein performing a maximum-likelihood position estimation method comprises applying a contracting-grid search algorithm and a forward model to predict values for subsequent iterations of the contracting-grid search algorithm to output a final energy deposition location and a final estimated deposited energy upon convergence of the algorithm, including by:
(a) defining a three-dimensional grid of test locations comprising a grid spacing and a center, the center being set at the estimated energy deposition location;
(b) calculating, for each of the test locations, predicted values using the forward model;
(c) computing, for each of the test locations, a merit function based on the predicted values and the measured values;
(d) selecting one of the test locations as a best match location based on the computed merit functions;
(e) if the best match location satisfies a convergence criteria, outputting the best match location as the final energy deposition location and outputting the sum of the predicted values corresponding to the best match location as the final estimated deposited energy; and
(f) if the best match location does not satisfy the convergence criteria, performing a next iteration of the contracting-grid search algorithm by contracting the grid spacing and setting the best match location as the estimated energy deposition location and then repeating steps (a) through (f) using the contracted grid spacing and the best match location as the grid center to provide test locations until one of the test locations selected as the best match location satisfies the convergence criteria.

18. The system of claim 16, wherein the forward model simulates the signal being generated in the region of energy deposition.

19. The system of claim 16, comprising a detector comprising a two-dimensional array of pixel electrodes, each pixel electrode having a pixel electrode center, wherein a pixel electrode of the two-dimensional array of pixel electrodes has an extent that is farther from its pixel electrode center than half a distance between the pixel electrode center and an adjacent neighbor's pixel electrode center, and wherein the detector is configured to provide the measured values.

20. The system of claim 16, wherein the memory is further configured to provide the processor with instructions which when executed cause the processor to:
receive measured data comprising a pixel array, each pixel in the pixel array having a measured pixel output value; and
select a subset of pixels in the pixel array based on measured pixel output values that indicate a signal being generated in a region of energy deposition, the signal having been induced in pixel electrodes corresponding to the selected subset of pixels, wherein the measured values comprise the measured pixel output values of the selected subset of pixels, wherein the deposited energy in the region of energy deposition is estimated based at least in part on the measured pixel output values, wherein the energy deposition location is estimated based at least in part on the measured pixel output values for the selected subset of pixels and a center-to-center spacing between the pixel electrodes corresponding to the selected subset of pixels, and wherein the predicted values comprise predicted pixel output values for the selected subset of pixels.
